(19) United States
(12) Patent Application Publication
(10) Pub. No.: US 2019/0229252 A1
(43) Pub. Date: Jul. 25, 2019

(54) SEMICONDUCTOR AND THERMOELECTRIC MATERIALS AND METHODS OF MAKING THE SAME USING SELECTIVE LASER MELTING

(71) Applicant: The George Washington University, Washington, DC (US)

(72) Inventors: Saniya LEBLANC, Chevy Chase, MD (US); Haidong Zhang, Rockville, MD (US); Ahmed El Desouky, Vienna, VA (US); Michael Carter, New York, NY (US)

(21) Appl. No.: 16/256,707

(22) Filed: Jan. 24, 2019

Related U.S. Application Data
(60) Provisional application No. 62/621,384, filed on Jan. 24, 2018.

(51) Int. Cl. H01L 35/34; H01L 35/32; H01L 35/16

(52) U.S. Cl. CPC H01L 35/34; H01L 35/16; H01L 35/32

(57) ABSTRACT

Methods of fabricating a shaped material includes laser irradiating a first layer of a powder to convert the powder to a first material layer; disposing a second layer of the powder on the first material layer; laser irradiating the second layer of the powder to convert the powder to a second material layer; and fusing the first material layer and the second material layer, forming a shaped material having semiconducting or thermoelectric properties. A system to fabricate a shaped material includes an enclosure; a powder containment vessel within the enclosure and having a base, a powder storage section and a shaped material formation section adjacent to the storage section; a transfer mechanism for transferring a powder from the storage section to the formation section; and a laser to irradiate the powder when the powder is located within the formation section.

### CROSS-REFERENCE TO RELATED APPLICATION

This application claims the benefit of U.S. Provisional Application No. 62/621,384, filed Jan. 24, 2018, the contents of which are incorporated by reference herein in its entirety.

### STATEMENT REGARDING FEDERALLY SPONSORED RESEARCH OR DEVELOPMENT

This invention was made with Government support under Grant/Subcontract No. 4000145175 awarded by the Oak Ridge National Laboratory Manufacturing Demonstration Facility RAMP-UP. The U.S. government may have certain rights in this invention.

### FIELD OF THE INVENTION

The present invention relates to methods of laser sintering and melting semiconductor and thermoelectric materials. More specifically, the present invention relates to methods of forming semiconductor and thermoelectric materials having various shapes and dimensions from semiconductor or thermoelectric material powders using continuous wave or pulsed wave laser sintering and melting methods.

### BACKGROUND OF THE DISCLOSURE

Thermoelectric semiconductor devices have unique advantages for thermal to electrical energy conversions or electrical to thermal energy conversions. As heat engines, thermoelectric generators can directly generate electricity from waste heat via the Seebeck effect; thermoelectric coolers, on the other hand, provide solid state cooling through the Peltier effect. Both thermoelectric generators and coolers have no mechanically moving parts, so they are more compact than standard power generation and refrigeration systems. Despite these advantages, thermoelectric devices have failed to become widespread in energy efficiency and thermal management applications in part because current manufacturing processes utilize a complex set of traditional manufacturing techniques, which limits device design and adaptability. Additionally, current production methods generally result in materials exhibiting low energy conversion efficiencies.

The performance of a thermoelectric material is usually evaluated through the thermoelectric figure of merit, a dimensionless value ZT=(S²σ/k)T, where S is the Seebeck coefficient, σ is the electrical conductivity, k is the thermal conductivity, and T is the temperature. A high ZT is indicative of a high efficiency thermoelectric device. Substantial research has therefore been conducted on materials, from bulk to films, nanowires, and quantum dots, in order to increase the ZT values of materials. However, the development of device fabrication techniques has not satisfied needs for the development of high efficiency materials and the ever-growing requirement for rapid construction of complex thermoelectric structures on a commercial scale. Materials improvements have largely been limited to laboratory scale demonstrations, while device-level improvements continue to be limited by processing and device engineering difficulties.

Traditionally, thermoelectric device manufacturing involves a series of processing steps such as hot pressing, dicing, polishing, metallization, brazing, and assembly. The lengthy process inevitably leads to low production rate, limited yield, and high cost. For example, thermoelectric materials are typically expensive because they must be high purity and sometimes require rare earth elements, and the ingot dicing step wastes approximately 50% of this high-value material. More importantly, the traditional fabrication technique does not provide any capability to adapt the device geometry for optimal performance or system integration. Most thermoelectric units are made as cuboids because it is challenging to produce crack-free parts of any other shape with the current manufacturing approach. These limitations hinder the development of thermoelectric devices with broad applicability. Improvements in materials processing and manufacturing methods are needed to advance thermoelectric device technology.

### BRIEF DESCRIPTION OF THE DRAWINGS

FIG. 1 is a schematic illustration of an exemplary process for the fabrication of a shaped thermoelectric material from a powder material;

FIG. 2 is a schematic illustration of another exemplary process for the fabrication of a shaped thermoelectric material from a powder material;

FIG. 3 is a schematic illustration of system for use in an exemplary process for the fabrication of a shaped thermoelectric material from a powder material;

FIG. 4 is a scanning electron microscope (SEM) image of the a Bi₂Te₃ powder (scale bar=100 μm) used in accordance with various aspects of the present disclosure;

FIG. 5 is an SEM image showing a polished cross-section of an unprocessed Bi₂Te₃ powder compact (scale bar=100 μm) prepared in accordance with various aspects of the present disclosure;

FIG. 6 is a graph illustrating temperature variant and invariant solid phase thermal conductivity of Bi₂Te₃ powder compacts used in a numerical modelling study in accordance with various aspects of the present disclosure;

FIG. 7 is an SEM image of a polished cross-section of a Bi₂Te₃ powder compact subjected to pulsed wave laser irradiation with an average output power of 3 W (same scale bar as FIG. 9), in accordance with various aspects of the present disclosure;

FIG. 8 is an SEM image of a polished cross-section of a Bi₂Te₃ powder compact subjected to pulsed wave laser irradiation with an average output power of 4 W (same scale bar as FIG. 9), in accordance with various aspects of the present disclosure;

FIG. 9 is an SEM image of a polished cross-section of a Bi₂Te₃ powder compact subjected to pulsed wave laser irradiation with an average output power of 5 W (scale bar=100 μm), in accordance with various aspects of the present disclosure;

FIG. 10 is a surface SEM image of a Bi₂Te₃ powder compact subjected to pulsed wave laser irradiation with an average output power of 3 W (750×magnification);

FIG. 11 is a surface SEM image of a Bi₂Te₃ powder compact subjected to pulsed wave laser irradiation with an average output power of 3 W (5000×magnification; same scale bar as FIG. 15);

FIG. 12 is a surface SEM image of a Bi₂Te₃ powder compact subjected to pulsed wave laser irradiation with an average output power of 4 W (750×magnification);

FIG. 13 is a surface SEM image of a Bi₂Te₃ powder compact subjected to pulsed wave laser irradiation with an average output power of 4 W (5000×magnification; same scale bar as FIG. 15);

FIG. 14 is a surface SEM image of a Bi₂Te₃ powder compact subjected to pulsed wave laser irradiation with an average output power of 5 W (750×magnification);

FIG. 15 is a surface SEM image of a Bi₂Te₃ powder compact subjected to pulsed wave laser irradiation with an average output power of 5 W (5000×magnification; scale bar=30 μm);

FIG. 16 a polarized light micrograph of a polished cross-section of a Bi₂Te₃ powder compact subjected to pulsed wave laser irradiation with an average output power of 5 W (scale bar=100 μm), in accordance with various aspects of the present disclosure

FIG. 17 is an in-situ image of a molten pool formed in a Bi₂Te₃ powder compact, 4.8 μs after a laser sintering pulse (same scale bar as FIG. 22);

FIG. 18 is a processed composite image of the in-situ image of a molten pool formed in a Bi₂Te₃ powder compact—the composite image corresponds to ten consecutive frames centered on 4.8 μs after a laser sintering pulse (same scale bar as FIG. 22);

FIG. 19 is an in-situ image of a molten pool formed in a Bi₂Te₃ powder compact, 50 μs after a laser sintering pulse (same scale bar as FIG. 22);

FIG. 20 is a processed composite image of the in-situ image of a molten pool formed in a Bi₂Te₃ powder compact—the composite image corresponds to ten consecutive frames centered on 50 μs after a laser sintering pulse (same scale bar as FIG. 22);

FIG. 21 is an in-situ image of a molten pool formed in a Bi₂Te₃ powder compact, 194.8 μs after a laser sintering pulse (same scale bar as FIG. 22);

FIG. 22 is a processed composite image of the in-situ image of a molten pool formed in a Bi₂Te₃ powder compact—the composite image corresponds to ten consecutive frames centered on 194.8 μs after a laser sintering pulse (scale bar=1 mm);

FIG. 23 is an illustration showing temperature contours when the maximum width and depth of a molten region formed in a Bi₂Te₃ powder compact in a numerical simulation for 5 W average laser power;

FIG. 24 shows graphs illustrating the evolution of the peak temperature observed in numerical models over time: (a) is a graph showing the evolution of peak temperature observed in a temperature invariant (TI) model and (h) is a graph showing the evolution of peak temperature observed in a Maxwell-Eucken (M-E) model;

FIG. 25 is an illustration showing numerical model simulations (TI and M-E) of molten pool size and shape for a laser average power of 5 W, at 5, 50 and 195 μs after the pulse at t=7.815 ms.

FIG. 26 is a graph illustrating changes in molten pool width over time under an M-E numerical model simulation;

FIG. 27 is a graph illustrating changes in molten pool width over time under an TI numerical model simulation;

FIG. 28 is a graph comparing measured widths, w₁ and w₂, of processed regions of a Bi₂Te₃ powder compact, to the maximum width of the molten pool observed in M-E and TI numerical model simulations, w_{M-E} and w_{TI};

FIG. 29 is a graph comparing measured depths, d₁ and d₂, of processed regions of a Bi₂Te₃ powder compact to the maximum depth of the molten pool observed in M-E and TI numerical model simulations, d_{M-E} and d_{TI};

FIG. 30 is an optical image of a thermoelectric material ingot (8 mm diameter and over 1 mm thick) made from commercially available Bi₂Te₃ powder using a layer-by-layer selective laser melting (SLM) approach in accordance with various aspects of the present disclosure;

FIG. 31 is an optical image of another thermoelectric material ingot (8 mm diameter and over 1 mm thick) made from commercially available Bi₂Te₃ powder using a layer-by-layer selective laser melting approach in accordance with various aspects of the present disclosure;

FIG. 32 is a scanning electron micrograph of a polished cross-section of an Bi₂Te₃ thermoelectric material formed by SLM processing of a Bi₂Te₃ powder sample, in-plane along the build direction (perpendicular to the laser scan direction);

FIG. 33 is a graph showing powder x-ray diffraction (PXRD) profiles of a Bi₂Te₃ powder sample (“Original”), a Bi₂Te₃ powder sample subjected to an SLM process (“SLM Processed”), and a reference Bi₂Te₃ PXRD database profile (“PDF #00-015-0863”);

FIG. 34 is graph comparing the Seebeck coefficients and electrical resistivities of various thermoelectric materials formed in accordance with various aspects of the present disclosure;

FIG. 35 is a graph of the Seebeck coefficient (circle) and electrical conductivity (square) from 50-473° C. for a Bi₂Te₃ powder sample subjected to an SLM process in accordance with various aspects of the present disclosure (conductivity data averaged over a set of ten measured values, and showing an uncertainty bar representing the standard deviation; the uncertainty on the measured Seebeck coefficient is ±7%, according to measurement equipment specifications);

FIG. 36 is a graph of the specific heat (square) and thermal diffusivity (triangle) from 30-500° C. for a Bi₂Te₃ powder sample subjected to an SLM process in accordance with various aspects of the present disclosure (the uncertainty for the specific heat and thermal diffusivity are ±5% and ±5%, respectively, according to measurement equipment specifications);

FIG. 37 is a graph of the thermal conductivity (filled circle) and thermoelectric figure of merit, ZT (open circle) from 30-500° C. for a Bi₂Te₃ powder sample subjected to an SLM process in accordance with various aspects of the present disclosure;

FIG. 38 is a scanning electron micrograph of a commercial Bi₂Te₃ powder which has been separated through a −270 mesh (53 μm) sieve;

FIG. 39 is a scanning electron micrograph of a standard stainless steel SS340 atomized powder;

FIG. 40 is a graph with images of various Bi₂Te₃ thermoelectric materials formed in accordance with various aspects of the present disclosure;

FIG. 41 is an image of an S-shaped Bi₂Te₃ thermoelectric material formed in accordance with various aspects of the present disclosure;

FIG. 42 shows images of various ZrNiSn thermoelectric materials formed in accordance with various aspects of the present disclosure;

FIG. 43 is a graph showing PXRD profiles of a reference ZrNiSn powder (PDF23-1281), a ZrNiSn thermoelectric material formed according to an SLM process at 25 W of laser output power (ground into a powder for PXRD analysis), a ZrNiSn thermoelectric material formed according to an SLM process at 35 W of laser output power (ground into a powder for PXRD analysis), and a ZrNiSn thermoelectric material formed according to an SLM process at 40 W of laser output power (ground into a powder for PXRD analysis);

FIG. 44 is a graph showing thermogravimetric (TGA) profiles, from room temperature to 800° C. of a reference ZrNiSn powder (PDF23-1281), and a ZrNiSn thermoelectric material formed according to an SLM process (30 W of laser output power, 350 mm/s scan speed, 25 μm hatch distance);

FIG. 45 is a graph showing an expanded portion of the graph of FIG. 44;

FIG. 46 shows images of various Hf_{0.3}Zr_{0.7}CoSn_{0.3}Sb_{0.7}/nano-ZrO₂ thermoelectric materials formed in accordance with various aspects of the present disclosure;

FIG. 47 is a graph showing PXRD profiles of a Hf_{0.3}Zr_{0.7}CoSn_{0.3}Sb_{0.7}/nano-ZrO₂ powder prior to subjecting to an SLA process, a Hf_{0.3}Zr_{0.7}CoSn_{0.3}Sb_{0.7}/nano-ZrO₂ thermoelectric material formed according to an RAI process (20 W laser output power, 350 mm/s scan speed, 10 μm hatch distance; sample ground into a powder for PXRD analysis), and a Hf_{0.3}Zr_{0.7}CoSn_{0.3}Sb_{0.7}/nano-ZrO₂ thermoelectric material formed according to an SLM process (25 W laser output power, 350 mm/s scan speed, 25 μm hatch distance; sample ground into a powder for PXRD analysis); and

FIG. 48 is a graph showing TGA profiles of a Hf_{0.3}Zr_{0.7}CoSn_{0.3}Sb_{0.7}/nano-ZrO₂ powder prior to subjecting to an SLM process, a Hf_{0.3}Zr_{0.7}CoSn_{0.3}Sb_{0.7}/nano-ZrO₂ thermoelectric material formed according to an SLM process (20 W laser output power, 350 mm/s scan speed, 10 μm hatch distance), and a Hf_{0.3}Zr0.7CoSn_{0.3}Sb_{0.7}/nano-ZrO₂ thermoelectric material formed according to an SLM process (25 W laser output power, 350 mm/s scan speed, 25 μm hatch distance).

### DETAILED DESCRIPTION

The following description of the embodiments is merely exemplary in nature and is in no way intended to limit the subject matter of the present disclosure, their application, or uses.

As used throughout, ranges are used as shorthand for describing each and every value that is within the range. Any value within the range can be selected as the terminus of the range. Unless otherwise specified, all percentages and amounts expressed herein and elsewhere in the specification should be understood to refer to percentages by weight.

For the purposes of this specification and appended claims, unless otherwise indicated, all numbers expressing quantities, percentages or proportions, and other numerical values used in the specification and claims, are to be understood as being modified in all instances by the term “about.” The use of the term “about” applies to all numeric values, whether or not explicitly indicated. This term generally refers to a range of numbers that one of ordinary skill in the art would consider as a reasonable amount of deviation to the recited numeric values (i.e., having the equivalent function or result). For example, this term can be construed as including a deviation of ±10 percent, alternatively ±5 percent, alternatively ±1 percent, alternatively ±0.5 percent, and alternatively ±0.1 percent of the given numeric value provided such a deviation does not alter the end function or result of the value. Accordingly, unless indicated to the contrary, the numerical parameters set forth in this specification and attached claims are approximations that can vary depending upon the desired properties sought to be obtained by the present invention.

It is noted that, as used in this specification and the appended claims, the singular forms “a,” “an,” and “the,” include plural references unless expressly and unequivocally limited to one referent. As used herein, the term “include” and its grammatical variants are intended to be non-limiting, such that recitation of items in a list is not to the exclusion of other like items that can be substituted or added to the listed items. For example, as used in this specification and the following claims, the terms “comprise” (as well as forms, derivatives, or variations thereof, such as “comprising” and “comprises”), “include” (as well as forms, derivatives, or variations thereof, such as “including” and “includes”) and “has” (as well as forms, derivatives, or variations thereof, such as “having” and “have”) are inclusive (i.e., open-ended) and do not exclude additional elements or steps. Accordingly, these terms are intended to not only cover the recited element(s) or step(s), but may also include other elements or steps not expressly recited. Furthermore, as used herein, the use of the terms “a” or “an” when used in conjunction with an element may mean “one,” but it is also consistent with the meaning of “one or more,” “at least one,” and “one or more than one,” Therefore, an element preceded by “a” or “an” does not, without more constraints, preclude the existence of additional identical elements.

The uncharacteristic properties of thermoelectric material powders create unique challenges for their processing via selective laser melting (SLM). For example, spreading powder layers is more difficult for thermoelectric materials than for the more common metals or alloys. Generally, metallic powders used in SLM have particles with spherical morphology, but the morphology of thermoelectric powder particles is highly irregular. As a result, the flowability for thermoelectric powders is generally worse than that of metals, and consequently, powder bed qualities are usually different in density and surface flatness. Furthermore, the thermal conductivity and thus thermal dissipation are higher in metals than in thermoelectric materials. The powder bed properties and the light-matter interactions are very different when comparing thermoelectric, metallic or ceramic materials, so the process parameters which are suitable for metals or ceramics may be different, sometimes by a large amount, for thermoelectric materials. Due to differences in thermal and optical properties, the process parameters are also material-dependent even within the category of thermoelectric materials. In the present disclosure, SLM (also known as laser powder bed fusion and direct metal laser sintering) is used as an additive manufacturing technique to build thermoelectric materials of various shapes and sizes in a layer-by-layer fashion. In the present disclosure, thermoelectric materials are made from powders of starting materials according to various methods.

According to various aspects of the present disclosure, thermoelectric materials of various shapes and sizes can be made via SLM from chalcogenide powder(s). In some instances, SLM can be used to make thermoelectric materials that are, for example, cubic, cuboidal (or rectangular prismatic), pyramidal (square pyramidal, triangular pyramidal, hexagonal pyramidal, etc), triangular prismatic, hexagonal prismatic, octagonal prismatic, cylindrical, spherical, hemispherical, conical, frustoconical, rhombic, a dumbbell, a tows, a star, a cross, a letter, a number, a symbol, a beam (W-shape, M-shape, S-shape, HP-shape, C-shape, L-shape, WT-shape, ST shape, HSS shape), a structured grid (mesh/lattice structure), an unstructured grid (mesh/lattice structure), a hybrid grid (mesh/lattice structure), a 3D object with holes or inside hollow space, or any combination thereof.

According to various aspects of the present disclosure, thermoelectric materials of various shapes and sizes can be made via SLM from chalcogenide powder(s). In some instances, thermoelectric chalcogenide materials such as Bi₂Te₃, Bi₂Se₃, Sb₂Te₃, Sb₂Se₃, PbSe, PbTe, PbSe₂, PbTe₂, SnSe, SnTe, SnSe₂, SnTe₂, AgSbTe₂, AgₓSb_{y}Te₂ (0<x,y<2), AgSbSeₓTe₂₋ₓ (0<x<2), AgₙPbₘMₙTeₘ₊₂ₙ (M=Sb, Bi; m, n are numbers; denoted as “LAST”), AgₓPb_{y}M_{z}Teₚ (M=Sb, Bi; x, y, z, p are numbers), AgₓPbₘSnₙSb_{y}Te₂₊ₘ₊ₙ (m, n, x, y are numbers; denoted as “LASTT”), (AgₓPbTe)_{y}(Ag₂Te)_{1-y} (x is a number; 0<y<1), La₃₋ₓTe₄ (0<x<3), GdSe, CuAgSe, Bi₂S₃, In₄Se_{3-δ} (0<δ<3), AgSbTe₂/GeTe, CsBi₄Te₆, Tl₉BiTe₆, Ag₉TlTe₅, Tl₂SnTe₅, KBi₃S₅, KBi_{6.33}S₁₀, K₂Bi₈S₁₃, α-,β-K₂Bi₈Se₁₃, K_{2.5}Bi_{8.5}Se₁₄, AₓBi₄Se₇ (x=1, 2), BaBiTe₃, CsBi₄Te₆, ALn_{1±x}Bi_{4±x}S₈ (A=K, Rb; Ln=La, Ce, Pr, Nd), BaLa—Bi₂Q₆ (Q=S, Se), α,β-APbBi₃Se₆ (A=K, Rb, Cs), K₁₋ₓSn₅₋ₓBi₁₁₊ₓSe₂₂, A₁₊ₓM′₄₋₂ₓBi₇₊ₓSe₁₅ (A=K, Rb; M′=Sn, Pb), Sn₄Bi₂Se₇, SnBi₄Se₇, CdBi₂S₄, CdBi₄S₇, Cd_{2.8}Bi_{8.1}S₁₅, Cd₂Bi₆S₁₁, Ba₃Bi_{6.67}Se₁₃, and Ba₃MBi₆Se₁₃ (M=Sn, Pb) can be formed from powders thereof. In some instances, thermoelectric chalcogenide materials such as BiₓSb₂₋ₓTe₃, where 0<x<2, can be made from a mixture of Bi, Sb, and Te powders. In some instances, thermoelectric chalcogenide materials such as A₂Te₃₋ₓSeₓ, where 0<x<3 and A is Bi or Sb, can be made from a mixture of A₂Te₃ and A₂Se₃ powders. In some instances, thermoelectric chalcogenide materials such as A′Te₁₋ₓSeₓ, where 0<x<1 and A′ is Ph or Sn, can be made from a mixture of A′Te and A′Se powders. In some instances, thermoelectric chalcogenide materials such as A″Te₂₋ₓSeₓ, where 0<x<2 and A″ is Pb or Sn, can be made from a mixture of A″Te₂ and A″Se₂ powders. In some instances, any of the above thermoelectric chalcogenide materials can be mixed with certain ratio to form a mixture or alloy, for example, BiₓSb₂₋ₓTe_{y}Se_{3-y}, where 0<x<2 and 0<y<3. In some instances, any of the above thermoelectric chalcogenide materials can be doped with one or more of, for example, Na, K, B, Al, Ga, C, Si, Ge, In, Tl, S, Sb, Sn, Se, Te, Li, Cu, Ag, Bi, CuBr, SbI₃, or ZnAlO by adding a dopant source to the powder(s). In some instances, any of the above thermoelectric chalcogenide materials (doped or un-doped) can be in conjunction with other conductors such as Ni, Pb to form a composite structure. In some instances, any of the above thermoelectric chalcogenide materials may contain nanostructures, nanocomposites, and nanoinclusions, for example, quantum dots, nanoparticles, nanowires, nanosheets, nanorods, nanoribbons, nanostructured films, and superlattices.

According to various aspects of the present disclosure, thermoelectric materials of various shapes and sizes can be made via SLM from powder(s) of a half-Heuster compound(s). In some instances, thermoelectric half-Heusler materials having a general formula XTZ, wherein X=Ti, V, Zr, Hf, Nb, Mn, Ln, T=Fe, Co, Ni, Rh, Pd, Pt, Ir, Z=Sn, Sb, Bi, can be formed from powders thereof. In some instances, thermoelectric half-Heusler materials having a general formula X¹ₐX²₁₋ₐT¹_{b}T²_{1-b}Z¹_{c}Z²_{1-c}, wherein X¹≠X², 1<a<0, T¹≠T², 1<b<0, Z¹≠Z², 1<c<0 can be formed from one or more powders of half-heulser materials. In some instances, thermoelectric half-Heusler materials having a general formula X¹ₐX²₁₋ₐTZ, wherein X¹≠X², 1<a<0, can be formed from one or more powders of half-heulser materials. In some instances, thermoelectric half-Heusler materials having a general formula XT¹_{b}T²_{1-b}Z, wherein T¹≠T², 1<b<0, can be formed from one or more powders of half-heulser materials. In some instances, thermoelectric half-Heusler materials having a general formula XTZ¹_{c}Z²_{1-c}, wherein Z¹≠Z², 1<c<0 can be formed from one or more powders of half-heulser materials. In some instances, thermoelectric half-Heusler materials having a general formula X¹ₐX²₁₋ₐTZ¹_{c}Z²_{1-c}, wherein X¹≠X², 1<a<0, Z¹≠Z², 1<c<0 can be formed from one or more powders of half-heulser materials. In some instances, thermoelectric half-Heusler materials having a general formula X¹ₐX²₁₋ₐT¹_{b}T²_{1-b}Z, wherein X¹≠X², 1<a<0, T¹≠T², 1<b<0, can be formed from one or more powders of half-heulser materials. In some instances, thermoelectric half-Heusler materials having a general formula. XT¹_{b}T²_{1-b}Z¹_{c}Z²_{1-c}, wherein T¹≠T², 1<b<0, Z¹≠Z², 1<c<0 can be formed from one or more powders of half-heulser materials. In some instances, any of the above thermoelectric half-heulser materials can be doped with one or more of, for example, Na, K, B, Al, Ga, C, Si, Ge, In, Tl, S, Sb, Sn, Se, Te, Li, Cu, Ag, Bi, CuBr, SbI₃, or ZnAlO by adding a dopant source to the powder(s). In some instances, any of the above thermoelectric half-Heusler materials may contain nanostructures, nanocomposites, and nanoinclusions, for example, quantum dots, nanoparticles, nanowires, nanosheets, nanorods, nanoribbons, nanostructured films, and superlattices.

According to various aspects of the present disclosure, thermoelectric materials of various shapes and sizes can be made via SLM from powder(s) of a full-Heusler compound(s). In some instances, thermoelectric full-Heusler materials having a general formula X₂TZ, wherein X=Ti, V, Zr, Hf, Nb, Mn, Ln, T=Fe, Co, Ni, Rh, Pd, Pt, Ir, Z=Sn, Sb, Bi, can be formed from powders thereof. In some instances, thermoelectric full-Heusler materials having a general formula X¹ₐX²₂₋ₐT¹_{b}T²_{1-b}Z¹_{c}Z¹_{1-c}, wherein X¹≠X², 2<a<0, T¹≠T², 1<b<0, Z¹≠Z², 1<c<0 can be formed from one or more powders of full-heulser materials. In some instances, thermoelectric full-Heusler materials having a general formula X¹ₐX²₂₋ₐTZ, wherein X¹≠X², 2<a<0, can be formed from one or more powders of full-Heulser materials. In some instances, thermoelectric full-Heusler materials having a general formula X₂T¹_{b}T²_{1-b}Z, wherein T¹≠T², 1<b<0, can be formed from one or more powders of full-Heulser materials. In some instances, thermoelectric full-Heusler materials having a general formula X₂TZ¹_{c}Z²_{1-c}, wherein Z¹≠Z², 1<c<0 can be formed from one or more powders of half-Heulser materials. In some instances, thermoelectric full-Heusler materials having a general formula X¹ₐX²₂₋ₐTZ¹_{c}Z¹_{1-c}, wherein X¹≠X², 2<a<0, Z¹≠Z², 1<c<0 can be formed from one or more powders of full-Heulser materials. In some instances, thermoelectric full-Heusler materials having a general formula X¹ₐX²₂₋ₐT¹_{b}T²_{1-b}Z, wherein X¹≠X², 2<a<0, T¹≠T², 1<b<0, can be formed from one or more powders of full-Heulser materials. In some instances, thermoelectric half-Heusler materials having a general formula X₂T¹_{b}T²_{1-b}Z¹_{c}Z²_{1-c}, wherein T¹≠T², 1<b<0, Z¹≠Z², 1<c<0 can be formed from one or more powders of full-Heulser materials. In some instances, any of the above thermoelectric full-heulser materials can be doped with one or more of, for example, Na, K, B, Al, Ga, C, Si, Ge, In, Tl, S, Sb, Sn, Se, Te, Li, Cu, Ag, Bi, CuBr, SbI₃, or ZnAlO by adding a dopant source to the powder(s). In some instances, any of the above thermoelectric full-Heusler materials may contain nanostructures, nanocomposites, and nanoinclusions, for example, quantum dots, nanoparticles, nanowires, nanosheets, nanorods, nanoribbons, nanostructured films, and superlattices.

According to various aspects of the present disclosure, thermoelectric materials of various shapes and sizes can be made via SLM from a mixture of powder comprising one or more half-Heusler compounds and one or more full-Heusler compounds. While many examples of half- and full-Heusler compounds are provided above, the examples are not intended to be limited. Over 1500 Heusler compounds have been investigated. Heusler compounds are generally understood to be magnetic intermetallics with face-centered cubic crystal structures and compositions of XYZ (half-Heuslers) or X₂YZ (full-Heuslers), where X and Y are transition metals and Z a p-block element. Structurally, half-Heusler compounds are understood as materials XYZ, having the Cl_{b} structure (space group F⁻ 43 m) consisting of a main group element Z from column IV or V of the periodic table, while Y is an early transition metal, and X is a late transition metal.

According to various aspects of the present disclosure, thermoelectric materials of various shapes and sizes can be made via SLM from powder(s) of electrically conductive silicide material(s). In some instances, thermoelectric metal silicide materials such as Cu₅Si, V₃Si, Cr₃Si, Mn₃Si, Fe₃Si, and Cr₂Si can be formed from powders thereof. In some instances, any of the above thermoelectric silicide materials can be doped with one or more of, for example, Na, K, B, Al, Ga, C, Si, Ge, In, Tl, S, Sb, Sn, Se, Te, Li, Cu, Ag, Bi, CuBr, SbI₃, or ZnAlO by adding a dopant source to the powder(s). In some instances, any of the above thermoelectric silicide materials may contain nanostructures, nanocomposites, and nanoinclusions, for example, quantum dots, nanoparticles, nanowires, nanosheets, nanorods, nanoribbons, nanostructured films and superlattices.

According to various aspects of the present disclosure, thermoelectric materials of various shapes and sizes can be made via SLM from powder(s) of copper ion material(s). In some instances, thermoelectric copper ion materials such as Cu₂Se can be formed from powders thereof. In some instances, any of the above thermoelectric copper ion materials can be doped with one or more of, for example, Na, K, B, Al, Ga, C, Si, Ge, In, Tl, S, Sb, Sn, Se, Te, Li, Cu, Ag, Bi, CuBr, SbI₃, or ZnAlO by adding a dopant source to the powder(s). In some instances, any of the above thermoelectric copper ion materials may contain nanostructures, nanocomposites, and nanoinclusions, for example, quantum dots, nanoparticles, nanowires, nanosheets, nanorods, nanoribbons, nanostructured films, and superlattices.

According to various aspects of the present disclosure, thermoelectric materials of various shapes and sizes can be made via SLM from powder(s) of Zintl material(s). In some instances, thermoelectric Zintl materials such as β-Zn₄Sb₃, YbZn₂Sb₂, Mg₃Sb₂, Na₂₊ₓGa₂₊ₓSn₄₋ₓ (0<x<4), BaGa₂Sb₂, K(Al/Ga)Sb₄, Yb₁₄MnₓA₁₋ₓSb₁₁ (A=Zn, Al; 0<x<1), A₁₄MPn₁₁ (A=alkaline earth or rare earth metal, M=transition or main group metal, and Pn=pnicogen) can be formed from powders thereof. In some instances, any of the above thermoelectric silicide materials can be doped with one or more of, for example, Na, K, B, Al, Ga, C, Si, Ge, In, Tl, S, Sb, Sn, Se, Te, Li, Cu, Ag, Bi, CuBr, SbI₃, or ZnAlO by adding a dopant source to the powder(s). In some instances, any of the above thermoelectric Zintl materials may contain nanostructures, nanocomposites, and nanoinclusions, for example, quantum dots, nanoparticles, nanowires, nanosheets, nanorods, nanoribbons, nanostructured films, and superlattices.

According to various aspects of the present disclosure, thermoelectric materials of various shapes and sizes can be made via SLM from powder(s) of magnesium-group IV element compounds. In some instances, thermoelectric magnesium-group IV element materials such as Mg₂Si, Mg₂Ge and Mg₂Sn can be formed from powders thereof. In some instances, any of the above thermoelectric magnesium-group IV element materials can be doped with one or more of, for example, Na, K, B, Al, Ga, C, Si, Ge, In, Tl, S, Sb, Sn, Se, Te, Li, Cu, Ag, Bi, CuBr, SbI₃, or ZnAlO by adding a dopant source to the powder(s). In some instances, any of the above thermoelectric magnesium-group IV element materials may contain nanostructures, nanocomposites, and nanoinclusions, for example, quantum dots, nanoparticles, nanowires, nanosheets, nanorods, nanoribbons, nanostructured films, and superlattices.

According to various aspects of the present disclosure, thermoelectric materials of various shapes and sizes can be made via SLM from powder(s) of inorganic clathrate compounds, such as those having general formulae AₓB_{y}C_{46-y} (type I) and AₓB_{y}C_{136-y} (type II), where B and C are group IIIA and IVA elements, respectively, which form the framework where “guest” A atoms (alkali or alkaline earth metal) are encapsulated in two different polyhedra facing each other. In sonic instances, any of the above thermoelectric inorganic clathrate materials can be doped with one or more of, for example, Na, K, B, Al, Ga, C, Si, Ge, In, Tl, S, Sb, Sn, Se, Te, Li, Cu, Ag, Bi, CuBr, SbI₃, or ZnAlO by adding a dopant source to the powder(s). In some instances, any of the above thermoelectric inorganic clathrate materials may contain nanostructures, nanocomposites, and nanoinclusions, for example, quantum dots, nanoparticles, nanowires, nanosheets, nanorods, nanoribbons, nanostructured films, and superlattices.

According to various aspects of the present disclosure, thermoelectric materials of various shapes and sizes can be made via SLIM from powder(s) of binary skutterudite compounds, such as those having the general formula AX₃, wherein A is Co, Fe, Rh, or Ir, and X is As, or Sb. In some instances, binary “filled skutterudite” compounds used to make thermoelectric materials. In binary “filled skutterudite” compounds, empty cages within a binary skutterudite framework can be filled by up to one ion (E) per A₄X₁₂ formula unit, leading to the “filled skutterudites” of formula E_{y}B₄X₁₂, where A=an alkali metal, an alkaline-earth metal, a rare-earth metal, an actinide, or Tl, and y is no greater than 1. In some instances, any of the above thermoelectric binary skutterudite materials can be doped with one or more of, for example, Na, B, Al, Ga, C, Si, Ge, In, Tl, S, Sb, Sn, Se, Te, Li, Cu, Ag, Bi, CuBr, SbI₃, or ZnAlO by adding a dopant source to the powder(s). In some instances, any of the above thermoelectric binary skutterudite materials may contain nanostructures, nanocomposites, and nanoinclusions, for example, quantum dots, nanoparticles, nanowires, nanosheets, nanorods, nanoribbons, nanostructured films, and superlattices.

According to various aspects of the present disclosure, thermoelectric materials of various shapes and sizes can be made via SLM from powder(s) of ternary skutterudite compounds. In some instances, ternary skutterudite compounds used to make thermoelectric materials can have the general formula NiGeX₂, wherein X is P or Bi. In some instances, ternary skutterudite compounds used to make thermoelectric materials can have the general formula ASb₂X, wherein A is Fe, Ru, or Os, and X is Se or Te. In some instances, ternary skutterudite compounds used to make thermoelectric materials can have the general formula AB_{1.5}X_{1.5}, wherein A is Co, Rh, or Ir, B is Ge or Sn, and X is S, Se or Te. In some instances, ternary skutterudite compounds used to make thermoelectric materials can have the general formula A_{0.5}B_{0.5}X₃, wherein A is Fe or Ru, B is Ni, Pd or Pt, and X is Sb or As. In some instances, the ternary skutterudite compound PtSn_{1.2}Sb_{1.8} can be used to make thermoelectric materials. In some instances, any of the above thermoelectric ternary skutterudite materials can be doped with one or more of, for example, Na, B, Al, Ga, C, Si, Ge, In, Tl, S, Sb, Sn, Se, Te, Li, Cu, Ag, Bi, CuBr, SbI₃, or ZnAlO by adding a dopant source to the powder(s). In some instances, any of the above thermoelectric ternary skutterudite materials may contain nanostructures, nanocomposites, and nanoinclusions, for example, quantum dots, nanoparticles, nanowires, nanosheets, nanorods, nanoribbons, nanostructured films, and superlattices.

According to various aspects of the present disclosure, thermoelectric materials of various shapes and sizes can be made via SLM from powder(s) of metal oxides, such as NaCo₂O₄, Ca₃Co₄O₉, (Bi,Pb)₂Sr₂Co₂O₈, TlSr₂Co₂O_{y}, (Hg,Pb)₂Sr₂Co₂O₇, SrTiO₃, ZnO, (ZnO)₃(In₂O₃), BiₓBa₁₋ₓCuSeO (0<x<1) or any combination thereof. In some instances, any of the above thermoelectric metal oxide materials can be doped with one or more of, for example, Na, K, B, Al, Ga, C, Si, Ge, In, Tl, S, Sb, Sn, Se, Te, Li, Cu, Ag, Bi, CuBr, SbI₃, or ZnAlO by adding a dopant source to the powder(s). Al-doped ZnO (Al_{0.02}Zn_{0.98}O) and Ca-doped (ZnO)₃(In₂O₃) are specific examples. In some instances, any of the above thermoelectric metal oxide materials may contain nanostructures, nanocomposites, and nanoinclusions, for example, quantum dots, nanoparticles, nanowires, nanosheets, nanorods, nanoribbons, nanostructured films, and superlattices.

According to various aspects of the present disclosure, thermoelectric materials of various shapes and sizes can be made via SLM from powder(s) of metal antimonides such as β-Zn₄Sb₃, Yb₁₄MnSb₁₁, and FeSb₂. In some instances, any of the above thermoelectric metal antimonide materials can be doped with one or more of, for example, Na, K, B, Al, Ga, C, Si, Ge, In, Tl, S, Sb, Sn, Se, Te, Li, Cu, Ag, Bi, CuBr, SbI₃, or ZnAlO by adding a dopant source to the powder(s). In some instances, any of the above thermoelectric metal antimonide materials may contain nanostructures, nanocomposites, and nanoinclusions, for example, quantum dots, nanoparticles, nanowires, nanosheets, nanorods, nanoribbons, nanostructured films, and superlattices.

According to various aspects of the present disclosure, thermoelectric materials of various shapes and sizes can be made via SLM from powder(s) of tetrahedrite compounds, such as those having the general formula Cu₁₂₋ₓMₓSb₄S₁₃, wherein M is Zn, Fe, Ni or any combination thereof. In some instances, any of the above thermoelectric tetrahedrite materials can be doped with one or more of, for example, Na, K, B, Al, Ga, C, Si, Ge, In, Tl, S, Sb, Sn, Se, Te, Li, Cu, Ag, Bi, CuBr, SbI₃, or ZnAlO by adding a dopant source to the powder(s). In some instances, any of the above thermoelectric tetrahedrite materials may contain nanostructures, nanocomposites, and nanoinclusions, for example, quantum dots, nanoparticles, nanowires, nanosheets, nanorods, nanoribbons, nanostructured films, and superlattices.

According to various aspects of the present disclosure, thermoelectric materials of various shapes and sizes can be made via SLM from powder(s) of a silicon-germanium compound having the general formula SiₓGe₁₋ₓ, wherein x=1-100. In some instances, any of the above thermoelectric silicon-germanium materials can be doped with one or more of, for example, Na, K, B, Al, Ga, C, Si, Ge, In, Tl, S, Sb, Sn, Se, Te, Li, Cu, Ag, Bi, CuBr, SbI₃, or ZnAlO by adding a dopant source to the powder(s). In some instances, any of the above thermoelectric silicon-germanium materials may contain nanostructures, nanocomposites, and nanoinclusions, for example, quantum dots, nanoparticles, nanowires, nanosheets, nanorods, nanoribbons, nanostructured films, and superlattices.

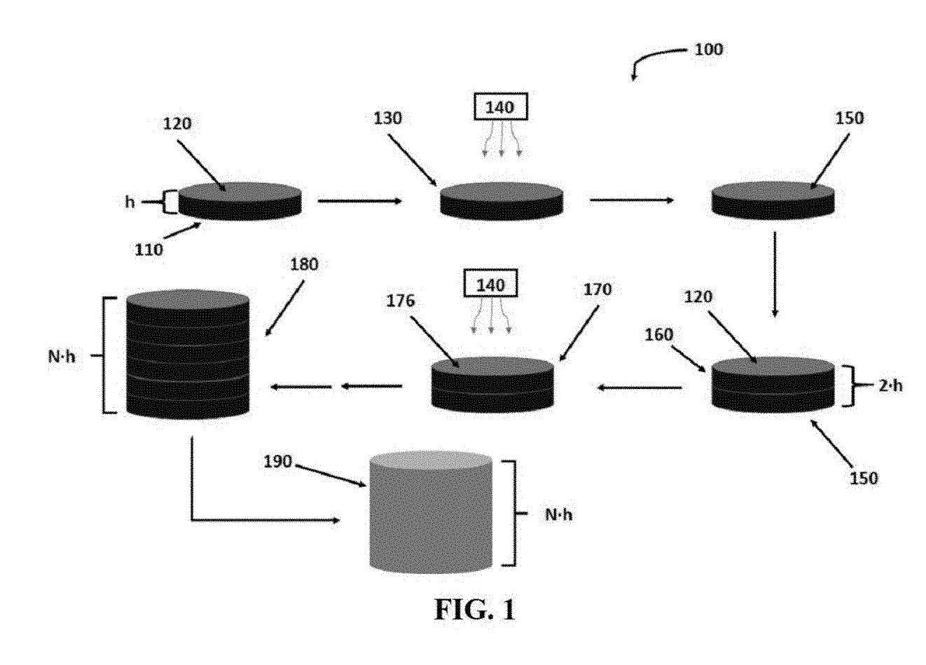

FIG. 1 is a schematic illustration of an exemplary process 100 for the fabrication of a shaped thermoelectric material by repetitive melting of layers of powder particles and fusion of adjacent layers. In the process 100, a thermally resistant ring 110, with a side-wall having a height (h), is filled with a powder material 120. In some instances, the thermally resistant ring 110 is made of stainless steel. In FIG. 1, the sidewall of thermally resistant ring 110 has a circular shape. In some instances, the sidewall of thermally resistant ring 110 can have a different shape such as, for example, a square, rectangle, triangle, hexagon, ovoid, semi-ovoid, a dumbbell, a cross, a letter, a number, a symbol, a beam (W-shape, M-shape, S-shape, HP-shape, C-shape, L-shape, WT-shape, ST shape, HSS shape), a structured grid (mesh/lattice structure), an unstructured grid (mesh/lattice structure), a hybrid grid (mesh/lattice structure), or any other suitable shape. The height (h) of the thermally resistant ring 110 can range from about 25 to about 350 μm, alternatively from about 50 to about 300 μm, alternatively from about 75 to about 250 μm, alternatively from about 100 to about 200 μm, and alternatively from about 125 to about 175 μm, In some instances, the 120 height (h) of the thermally resistant ring 110 is about 150 μm.

The powder material 120 is made to evenly fill the thermally resistant ring 110. In some instances, uniaxial pressure (up to 300 MPa) is utilized to form a compact powder bed within the thermally resistant ring 110. The resulting powder-filled ring 130 is then placed in a laser melting enclosure (not shown) and subjected to laser irradiation by a laser 140. The laser 140 scans the exposed surface of the exposed powder of the powder-filled ring 130 in a pre-defined pattern, to melt and fuse the powder material 120 and form a first layer 150 of a shaped thermoelectric material. Laser irradiation is generally conducted in the laser melting enclosure under an inert atmosphere such as N₂(g) or Ar(g). The laser melting enclosure can include oxygen sensor (not shown) to measure the oxygen level within the laser melting enclosure. Generally, it is desirable that the oxygen level of the laser melting enclosure is maintained at 10% or less, preferably 8% or less, more preferably 6% or less, more preferably 4% or less, and even more preferably 1% or less.

After formation of first layer 150, which is still contained within the first thermally resistant ring 110, a second thermally resistant ring 160 is stacked on the first thermally resistant ring 110 and filled with the powder material 120 as above to form a stacked ring configuration 170. The resulting stacked ring configuration 170 is then placed in a laser melting enclosure (not shown) and subjected to laser irradiation by the laser 140. The laser 140 scans the exposed surface of the exposed powder in the second thermally resistant ring 160 in a discussed above, to melt and fuse the powder material 120 and a second layer 176 of the shaped thermoelectric material. During this process, the first layer 150 and the second layer 176 fuse together.

The above process can be repeated any desired number (N) of times to produce a thermoelectric material 190 having a height of about Nil encased within N thermally resistant rings 180. After removal of the thermoelectric material 190 from the N thermally resistant rings 180, the external surfaces of the thermoelectric material 190 can be ground, polished, or otherwise mechanically smoothed to form a commercial shaped thermoelectric material product. In FIG. 1, N=6, but this is in no way intended to be limiting, and number of repetitions can be performed to form a shaped thermoelectric material of a desired height.

In FIG. 1, the heights of the first thermally resistant ring 110, the second thermally resistant ring 160, and each additional ring are dimensionally the same. In some instances, one or more of the thermally resistant rings can have a different height. In some instances, each of the rings can have the same general shape (for example, circular, square or triangular) but can be made to have incrementally smaller internal dimensions. For example, a thermoelectric material having a conical or frustoconical shape may be formed using a series of circular thermally resistant rings. Also for example, a square pyramidal thermoelectric material may be formed using a series of square rings. Also for example, a triangular pyramidal thermoelectric material may be formed using a series of triangular rings. In some instances, thermoelectric materials having more than one general shape can be formed.

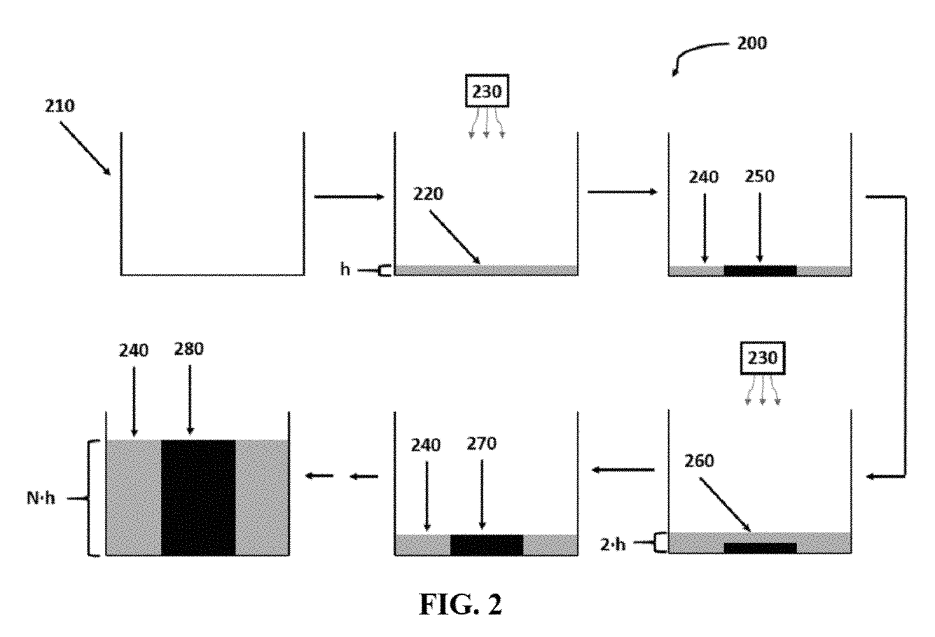

FIG. 2 is a schematic illustration of another exemplary process 200 for the fabrication of a shaped thermoelectric material by repetitive melting of layers of powder particles and fusion of adjacent layers. In process 200, a powder containment vessel 210 is provided. The powder containment vessel 210 can be placed on a support (not shown) that can move the powder containment vessel 210, vertically, horizontally, or any combination thereof. A first layer 220 of a powder material is placed in the vessel 220. The height (h) of the first layer 220 can range from about 25 to about 350 μm, alternatively from about 50 to about 300 μm, alternatively from about 75 to about 250 μm, alternatively from about 100 to about 200 μm, and alternatively from about 125 to about 175 μm. In some instances, the 120 height (h) of the thermally resistant ring 110 is about 150 μm. In some instances, uniaxial pressure (up to 300 MPa) is utilized to compact powder first layer 220 and/or to ensure the first layer 220 has a uniform height.

The vessel 210, with the first powder layer 220, is then placed in a laser melting enclosure (not shown) and subjected to laser irradiation by a laser 230. The laser 230 scans a predefined portion of the surface of the first layer 220 in a pre-defined pattern, to melt and fuse a portion of the powder material and form a first layer 250 of a shaped thermoelectric material. A non-irradiated amount of the powder material 240 remains. The laser 230 scanning process can be controlled such that the first layer 250 is formed to be any desired shape such as, for example, a circle, a polygon (triangle, square, rectangle, hexagon, trapezoid, etc.), an ovoid, a dumbbell, a cross, a letter, a number, a symbol, a beam (W-shape, M-shape, S-shape, HP-shape, C-shape, L-shape, WT-shape, ST shape, HSS shape), a structured grid (mesh/lattice structure), an unstructured grid (mesh/lattice structure), a hybrid grid (mesh/lattice structure), and so on. Laser irradiation is generally conducted in the laser melting enclosure under an inert atmosphere such as N₂(g) or Ar(g). The laser melting enclosure can include oxygen sensor (not shown) to measure the oxygen level within the laser melting enclosure. Generally, it is desirable that the oxygen level of the laser melting enclosure is maintained at 10% or less, preferably 8% or less, more preferably 6% or less, more preferably 4% or less, and even more preferably 1% or less.

After formation of first layer 250, a second powder layer 260 is applied onto the first layer 250 and the remaining first layer of powder 240, within the vessel 210. The vessel 210 is then placed in a laser melting enclosure (not shown) and subjected to laser irradiation by the laser 230. The laser 230 scans a predefined portion of the surface of the second layer 260 in a pre-defined pattern, to melt and fuse a portion of the powder material and form a second layer (not shown) of a shaped thermoelectric material. During this process, the first layer 240 and the second layer fuse together to form a shaped thermoelectric material 270.

The above process can be repeated any desired number (N) of times to produce a thermoelectric material 280 having a height of about N·H surrounded by powder material 240 that was not subjected to laser irradiation. After removal of the thermoelectric material 280 from the vessel 210 and the remaining powder material 240, the external surfaces of the thermoelectric material 280 can be ground, polished, or otherwise mechanically smoothed to form a commercial shaped thermoelectric material product. The number of repetitions (N) can be performed to form a shaped thermoelectric material of a desired height. The remaining powder material 240 can be recovered and reused in subsequent processes for the fabrication of shaped thermoelectric materials.

In FIG. 2, the heights of each powder layer have the same height and the laser scans the same pre-defined portion of each layer. In some instances, one or more of the layers can have a different height. In some instances, each of the layers can be subjected to laser irradiation such that a uniform general shape is produced such as, for example, a solid or longitudinally hollow cylinder, a cube, a solid or longitudinally hollow rectangular prism, a solid or longitudinally hollow triangular prism, a solid or longitudinally hollow hexagonal prism, a solid or longitudinally hollow octagonal prism, a structured grid (mesh/lattice structure), an unstructured grid (mesh/lattice structure), a hybrid grid (mesh/lattice structure), and so on. In some instances, each of the layers can be subjected to laser irradiation such that the area of irradiated powder incrementally decreases to form, for example, a solid or longitudinally hollow conical or frustoconical thermoelectric material, a square pyramidal thermoelectric material, or a triangular pyramidal thermoelectric material.

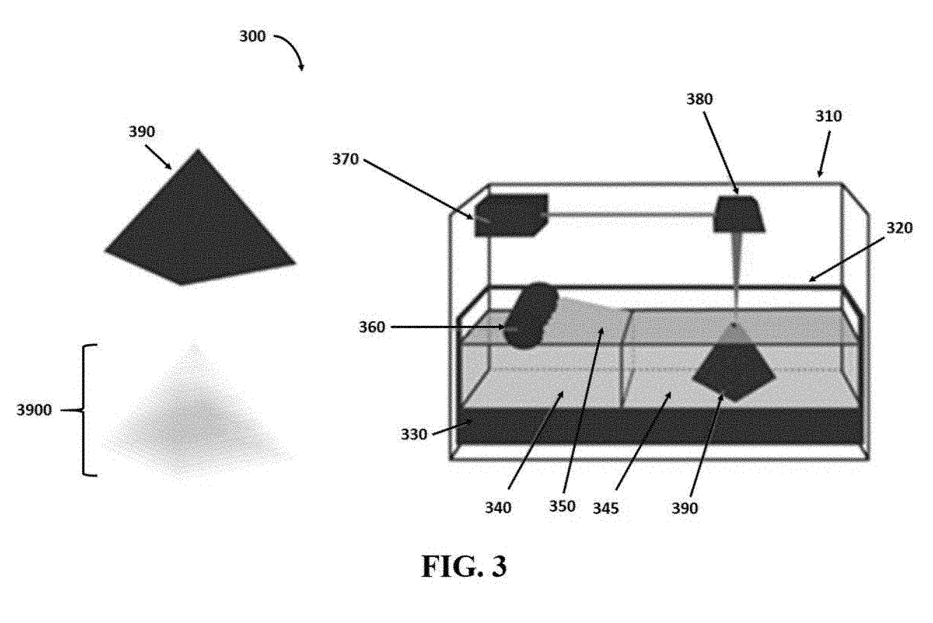

FIG. 3. illustrates an exemplary system 300 that can be employed in accordance with process 200 or another similar process. The exemplary system 300 can include a laser melting enclosure 310, a powder containment vessel 320, and a laser 370. The vessel 320 includes a base 330 and can be physically or artificially separated into a powder storage section 340 and a thermoelectric material formation section 345. The powder storage section 340 and a thermoelectric material formation section 345 are supported by the base 330. A transfer mechanism 360 can move a powder material 350 from the powder storage section 340 to the thermoelectric material formation section 345 and form a layer of powder material, having a uniform height, in the thermoelectric material formation section 345. In FIG. 3, the transfer mechanism 360 is shown as a roller. In some instances, the transfer mechanism 360 can be any one of a doctor blade, a brush, or a comb. In general, any machine that can move a powder material from powder storage section 340 to the thermoelectric material formation section 345 and form a layer of powder material, having a uniform height, in the thermoelectric material formation section 345, can be utilized. The system 300, can further include a beam focusing assembly 380, which can include a mid-power scanner with an F-theta lens (optionally mounted on an adjustable height platform), to control the position of the laser beam relative to the thermoelectric material formation section 345. The base 330 can be configured to move vertically (whether by means of hydraulics, pneumatics, a screw-driven assembly, or any other suitable means) within the vessel 320 to allow for multiple transfers of powder material 350 from the powder storage section 340 to the thermoelectric material formation section 345. In FIG. 3, a square pyramidal thermoelectric material 390 from is shown as being formed from fusion of a plurality of thermoelectric material layers 3900, by a layer-by-layer SLM process as described above.

In some instances, a continuous wave laser can be used in processes for the fabrication of a shaped thermoelectric material by repetitive melting of layers of powder particles and fusion of adjacent layers. The continuous wave laser can operate at a wavelength (λ) ranging from about 200 nm to about 11 μm. In some instances, the continuous wave laser can be a diode-pumped Ytterbium fiber laser. In some instances, the Ytterbium fiber laser can operate at a wavelength (λ) of between about 1030 nm and about 1080 nm, alternatively about 1070 nm. In some instances, the Ytterbium fiber laser can operate in continuous wave mode with an output power of up to 100 W. In other instances, any one of a CO₂ laser (λ˜10.6 μm), a Nd:YAG laser (λ˜1.064 μm), an Yb:YAG laser (λ˜1.03 μm), a Nd:YVO4 laser (λ˜1.064 μm), and a diode laser (λ˜810 nm, 980 nm) can be used as the continuous wave laser. In some instances, a mid-power scanner can be used to control the position of the laser beam. In some instances, a mid-power scanner with an F-theta lens mounted on an adjustable height platform can be used to control the position of the laser beam. The laser system combined with the scanner allows control of the laser scan pattern, hatch distance, and scan speed. In accordance with various aspects of the present disclosure, the output power of the laser can range from about 1 to about 500 W, alternatively from about 7.5 to about 200 W, alternatively from about alternatively from about 10 to about 100 W, and alternatively from about 15 to about 50 W. In accordance with various aspects of the present disclosure, the scan speed can range from about 5 to about 10000 mm/s, 30 to about 5000 mint's, 50 to about 1000 mm/s, 100 to about 800 mm/s, alternatively from about 200 to about 750 mm/s, alternatively from about 300 to about 700 mm/s, and alternatively from about 350 to about 650 mm/s. In accordance with various aspects of the present disclosure, the hatch distance can range from about 1 to about 1000 μm, alternatively from about 2 to about 500 μm, alternatively from about 3 to about 100 μm, alternatively from about 4 to about 37.5 μm, alternatively from about 5 to about 25 μm, alternatively from about 6 to about 15 μm, and alternatively from about 7 to about 10 μm. The laser beam which irradiates a powder sample can be focused to have a spot size of between about 1 and about 1000 μm, alternatively between about 10 and about 800 μm, alternatively between about 20 and about 600 μm, alternatively between about 25 and about 400 μm, alternatively between about 30 and about 300 μm, alternatively between about 35 and about 200 μm, alternatively between about 40 and about 100 μm, alternatively between about 40 and about 60 μm, and alternatively about 50 μm.

In some instances, a pulsed wave laser can be used in processes for the fabrication of a shaped thermoelectric material by repetitive melting of layers of powder particles and fusion of adjacent layers. The laser can operate at a wavelength (λ) ranging from about 200 nm to about 11 μm. In some instances, a dual head high pulse energy green Nd-YLF laser can be used. In some instances, the dual head high pulse energy green Nd-YLF laser can operate at a wavelength of 527 nm. In other instances, any one of a CO₂ laser (λ˜10.6 μm), a Nd:YAG laser (λ˜1.064 μm), an Yb:YAG laser (λ˜1.03 μm), a Nd:YVO4 laser (λ˜1.064 μm), a diode laser (λ˜810 nm, 980 nm), an Yb fiber laser (1.03 μm<λ<1.08 μm), a Cu-vapor laser (λ˜510.6 nm, 578.2 nm), and an excimer laser (193 nm<λ<351 nm) can be used as the pulsed wave laser.

The laser can have an average maximum output power of 200 W. In use, the pulsed wave laser can have an output power between about 0.25 and about 200 W, alternatively between about 0.3 and about 150 W, alternatively between about 0.35 and about 100 W, alternatively between about 0.4 and about 75 W, alternatively between about 0.5 and about 50 W, alternatively between about 0.75 and about 25 W, alternatively between about 1 and about 10 W, alternatively from about 2 to about 8 W, alternatively from about 3 to about 6 W, and alternatively from about 4 to about 5 W. The maximum repetition rate at such output powers can be between about a 3 Hz and about 100 GHz, alternatively between about 100 MHz and about 1 GHz, alternatively between about 1 MHz and about 50 MHz, alternatively between about 1.5 and about 100 kHz, alternatively between about 2 and about 50 kHz, alternatively between about 2.5 and about 25 kHz, alternatively between about 3 and about 10 kHz, alternatively between about 3.5 and about 7.5 kHz, alternatively between about 4 and about 6 kHz, and alternatively about 5 kHz. The laser beam which irradiates a powder sample can be focused to have a spot size of between about 1 and about 1000 μm, alternatively between about 25 and about 500 μm, alternatively between about 50 and about 400 μm, alternatively between about 100 and about 350 μm, alternatively between about 30 and about 300 μm, alternatively between about 35 and about 200 μm, alternatively between about 40 and about 100 μm, alternatively between about 40 and about 60 μm, and alternatively about 50 μm. In accordance with various aspects of the present disclosure, the scan speed, when using a pulsed wave laser can range from about 5 to about 10000 mm/s, alternatively from about 10 to about 5000 mm/s, alternatively from about 15 to about 1000 mm/s, alternatively from about 20 to about 500 mm/s, alternatively from about 20 to about 100 mm/s and alternatively about 30 to about 50 mm/s.

In some instances, the pulsed wave laser can be coupled with a linear motorized translation stage and a motion controller for a stepper motor. The laser beam can be focused on a powder material using a lens such as, for example, a 200 mm focal length converging lens. The translation stage, stepper motor, and lens can be used to control the scan speed as well as the distance between a powder material and the lens and, concomitantly, the spot size.

In some instances, the laser (whether continuous or pulsed wave) can be immobile, and a base on which the powder sample sits can be configured to move longitudinally and/or latitudinally, the longitudinal and/or latitudinal movement of the base relative to the immobile laser can vary one or more of the spot size of the laser beam irradiating the powder sample, the scan speed, the hatch distance, and the pattern of laser irradiation.

### EXAMPLES

### Experimental Study #1—Selective Laser Melting (SLM) of Bi₂Te₃ with a Pulsed-Wave Laser

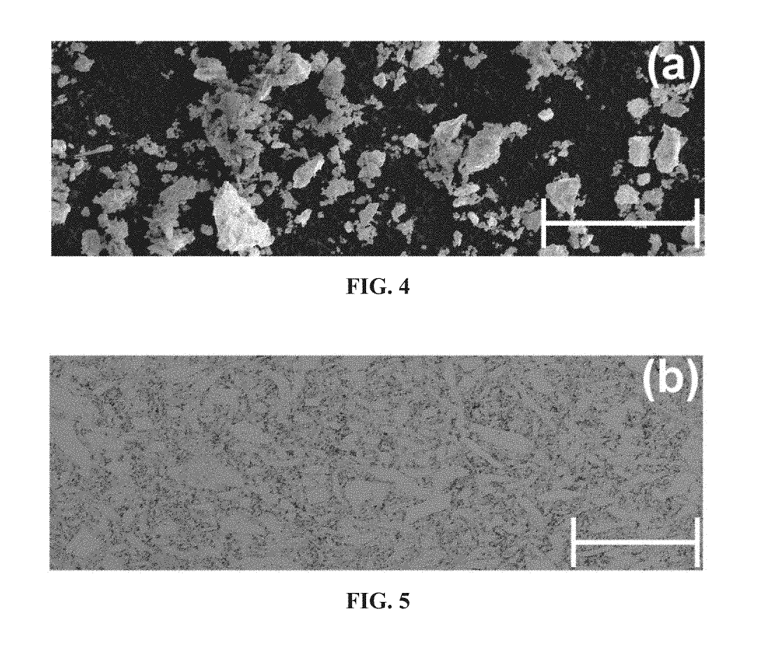

Experimental—Materials. For pulsed-wave laser melting Bi₂Te₃ powder (−325 mesh, 99.99% trace metal basis) was purchased from Sigma Aldrich and used as received. FIG. 4 is a scanning electron microscope (SEM) image of the Bi₂Te₃ powder (scale bar=100 μm). The powder morphology is highly irregular with a large number of aggregates and small diameter particles. The powder contains a wide range of equivalent spherical diameters, ranging from 1-70 μm. The particle size distribution skews heavily towards smaller diameters, less than 10 μm. The mean and median equivalent spherical diameters are 3.6 and 2.2 μm, respectively. The Bi₂Te₃ powder was observed to be difficult to spread in layers regardless of spreading blade type, so experiments were carried out on powder compacts. To form a powder compact, Bi₂Te₃ powder (0.1 g) was compacted using a 6 mm die, a Carver Laboratory press, under a uniaxial pressure of 295 MPa. The formed compacts were roughly 500 μm thick. FIG. 5 is an SEM image showing a polished cross-section of an unprocessed Bi₂Te₃ powder compact (scale bar=100 μm). The polished compact shows the wide distribution of particle sizes. The porosity of the polished cross-section was estimated via image analysis. Powder compacts used in all experiments had a porosity of ˜15%.

Experimental—Experimental Setup. A Photonics Industries DM Series dual head high pulse energy green Nd-YLF (DM527-30) pulsed laser was used for single scan lines in the Bi₂Te₃ powder compacts. The laser operates at a wavelength of 527 nm, and the maximum average power of the laser is 40 W. The maximum repetition rate at low power, 5 kHz, corresponds to 200 μs between pulses. The intensity of each pulse decreases as repetition rate increases. Lower peak power and intensity avoids ablative effects. The laser pulse duration, full-width at half maximum (FWHM) value, was measured using a photodiode (Thorlabs DET10A) at 4 W average laser power, and the power was measured with an Ophir Nova 2 powermeter. The FWHM pulse duration of the laser is 480 ns, much larger than other typical (Nd-YAG) pulsed lasers which have a pulse of 5-10 ns. The longer pulse duration minimizes ablative effects by reducing the laser intensity. The laser outputs a beam with multiple transverse modes (M2=13.6); its spatial profile still has a bell-shape and can be approximated as Gaussian.

An in-house setup having an Optics Focus linear motorized translation stage (MOX-03-200) and an Optics Focus motion controller for an NEMA17 stepper motor (MOC-01-1-110) was used to scan the powder compacts under the laser. The laser beam was focused using a 200 mm focal length converging lens and intersected the powder compact normally. The distance between the lens and the compact was adjusted to produce a spot size of 280 μm. Experimental trials were carried out at average powers of 1, 2, 3, 4 and 5 W (16.24, 32.48, 48.72, 64.96, 81.20 W/mm²), and a constant scan speed of 40 mm/s. A total of three samples were processed at each power level. All experimental trials were conducted in air.

Experimental—In-situ Observations via Stroboscopic Imaging. In-situ observations of the molten pool were made via stroboscopic imaging using a Vision Research Phantom V710 camera recording at 4990.02 Hz. The camera was fitted with a 105 mm Nikon lens at f=4 with a bellows which produced an image magnification of 6. A 550 nm long pass filter (Schott OG550) protected the camera sensor from the intense sintering pulse. Illumination was provided by a cell containing a solution of rhodamine 6G fluorescent dye pumped with the second laser cavity. This provided a uniform pulsed light source that transmits through the camera filter. The solution also prevents drawbacks such as a speckle pattern associated with illumination by coherent light. A Berkeley Nucleonics (Model 575) time-delay generator was used for synchronizing the laser and camera.

The first laser cavity was used for sintering. The repetition rate of the sintering pulse was set to 5 kHz. The beam diameter was scaled up to 1 mm to increase its image size and better resolve the details of the molten pool, and the power was scaled to 16 W. The power and beam diameter were scaled such that the in-situ imaging was performed at roughly the same linear energy density as the main processing experiment. The linear energy density (L) is defined in terms of the average power, P_{avg}, beam diameter, d, and scan speed, v:

$$L = \frac{{P}_{avg}}{vd} \qquad ( 1 )$$

The scan speed used in the in-situ imaging was the same as the main processing experiment, 40 mm/s. The difference in frequency between the sintering and imaging lasers results in a drift of 400 ns/pulse between the two. A composite video of the molten pool between pulses was built from images of the molten pool at slightly different times after different pulses. For the sample size, scan speed and drift used in this experiment, roughly 300 μs of molten pool evolution, corresponding to 1.5 laser pulses, was imaged.

Experimental—Characterization. Processed samples were cleaved normal to the laser scan direction and embedded in EpoxySet™. Polished cross-sections of the processed samples were prepared using an Allied High Tech Multiprep™ 8″ polishing system. Scanning electron microscopy was used to investigate the depth of consolidation and other morphological features of the polished cross-sections. Scanning electron micrographs were also taken of the surfaces of unpolished samples. Polarized light microscopy was used to image the microstructure of the polished cross-sections. Polarized light images were taken using a Leica DM 270011/1 microscope, and SEM images were taken using an FEI Teneo LV SEM.

Numerical Modelling Model Overview. A 2D thermal model of the nanosecond pulsed laser melting process was developed in COMSOL™. The model corresponds to a cut through the powder compact normal to the direction of processing. The model includes both heat transfer and phase change, and the pulse is modeled as a periodic boundary condition. The compact is approximated as a porous block of Bi₂Te₃ with temperature-dependent properties for the solid and liquid phases of Bi₂Te₃. Two thermal conductivity values, representing approximate upper and lower bounds for the powder compact thermal conductivity, were modeled for three average laser powers, 3, 4 and 5 W.

Numerical Modelling—Governing Equations. Heat transfer in the model is governed by the heat equation and Fourier's law, and the latent heat of melting/fusion is incorporated in the definition of the temperature-dependent specific heat capacity. The liquid phase of Bi₂Te₃ is modeled as a separate solid phase. This simplification is made due to the lack of important liquid and vapor phase property data for Bi₂Te₃. Surface tension, boiling point, latent heat of vaporization and Marangoni coefficient are not readily available and may have yet to be characterized for Bi₂Te₃. These properties are needed to accurately model physical phenomena, such as recoil pressure and Marangoni convection, that strongly influence melt flow dynamics in laser processing.

The heat equation and Fourier's law are simplified by assuming the physical behavior is invariant in the out-of-plane direction. The modified heat equation and Fourier's law are defined in Eqs. 2 and 3, below. Here, z is the out-of-plane dimension, ρ is the density, Cₚ is the specific heat capacity, T is the temperature, q is the conduction heat flux, K is the thermal conductivity and Q represents heat generation. In this model, z=1 μm, thus modeling the cross-section as an extremely thin rectangular volume. This small out-of-plane dimension also allows the laser heating to be consistently defined. An arbitrarily large value of z amounts to a non-physical stretching of the heat source in the out-of-plane direction. The choice of z has no impact on the model results as confirmed via an initial study of the model using a thickness of z=1 m and comparing the results with our model thickness choice z=1 μm. No out-of-plane heat transfer is included in the model, and the boundary conditions and heating source were defined such that they would scale with any choice of z. The mathematical description of heating due to a moving pulsed laser beam is described below.

$$\begin{matrix}z ρ {C}_{p} \frac{\partial T}{\partial t} + ∇ \cdot q = zQ & ( 2 ) \\ q = - zk ∇ T & ( 3 )\end{matrix}$$

The temperature-dependent specific heat capacity was modified to include latent heat of melting/fusion via a Gaussian function centered on the melting temperature.

$${C}_{p} = \{ \begin{matrix}{C}_{p , s} & T \leq {T}_{s} \\ {C}_{p , s} + {L}_{f} \frac{e - [ {( T - {T}_{m} )}^{2} / {( {T}_{1} - {T}_{o} )}^{2} ]}{\sqrt{{π ( {T}_{l} - {T}_{m} )}^{2}}} & {T}_{s} \leq T \leq {T}_{l} \\ {C}_{p , s} + {L}_{f} / {T}_{m} & {T}_{l} \leq T\end{matrix} \qquad ( 4 )$$

Here, L_{f} is the latent of fusion/melting, Tₘ is the melting temperature, Tₗ and Tₛ are the liquidus and solidus temperatures, and C_{p,s} is the specific heat capacity of the solid phase. The specific heat capacity of the liquid phase is approximated via C_{p,l}=C_{p,s}+L_{f}=Tₘ, and the liquidus and solidus temperatures are defined as T₁=Tₘ+10 K and Tₛ=Tₘ−10 K, respectively. Model parameters and material properties are summarized below.

Numerical Modelling—Model Setup—Model Geometry and Mesh. A 2D cut through the powder compact is modeled. The modeled region of the Bi₂Te₃ powder compact has a width of 1 mm and a depth of 0.5 mm. The sample holder (or substrate) is also included in the model as a 1 mm wide, 0.5 mm deep region of 304L stainless steel. The transverse symmetry of the problem was used to reduce the size of the computational domain by applying a symmetry boundary condition on the left edge of the domain. A mesh refinement study was conducted to active at the final mesh used in the model. An ultra-fine mesh was required to resolve the large temperature gradients due to the short duration, high intensity periodic heat flux, as well as the change in the temperature dependent thermophysical properties in a shallow region near the surface of the powder compact where phase change and large temperature gradients occurred. A linear element order was used to reduce solve times. The model was run on a multiprocessor server; solve times for a single model case were ˜8 hrs.

Numerical Modelling—Model Setup—Description of Heating due to the Moving Laser Beam. The heating due to the moving pulsed Gaussian laser beam is modeled as a periodic heat flux boundary condition on the top boundary of the 2D model. A widely used mathematical description for a 3D, continuous wave, moving Gaussian heat flux is adapted for use in this model. The modified periodic heat flux, q(x, t), is defined as:

$$q ( x , t ) = \frac{2 AP ( t )}{π ω} {e}^{- 2 {r ( x , t )}^{2} / {ω}^{2}} \qquad ( 5 )$$

Where A is the absorptivity, P(t) is the time varying power of the laser, ω is the beam radius where the intensity of the beam drops to 1/e² of its peak value, and the distance from the center of the Gaussian beam, r(x,t), is:

r(x, t)={square root over (z²+(v(t−t))²)} (6)

Here, x is the location along the x-axis, v is the velocity of the laser beam, t is time, and tₛ defines the offset of the laser beam at t=0 s. In this mathematical description of the heating due to the moving laser beam, the heat flux, due to the laser beam, is symmetric in the x-direction, centered on x=0 m, and moving in the out-of-plane, z-direction. The offset of the laser beam at t=0 s is set to tₛ=0.0075 s. Thus, the center of the laser beam starts 300 μm behind the modeled 2D plane at t=0 s.

Numerical Modelling—Model Setup—Description of Time-Varying Laser Power. The Non-Linear Least-Square Minimization and Curve-Fitting (LMFIT) package was used to fit built-in model functions to photodiode measurements of the laser pulse. A normal Gaussian distribution fit the photodiode data best. The normal Gaussian distribution function is:

$$g ( x ) = \frac{{A}_{p}}{σ \sqrt{2 π}} {e}^{- {( x - μ )}^{2} / 2 {σ}^{2}} \qquad ( 7 )$$

where Aₚ is the area under the curve, is the standard deviation and u is the mean. The fit parameters for the photodiode data were Aₚ=1.58×10⁻⁶ V·s, σ=1.85×10⁻⁷ s and μ=4.85×10⁻⁶ s. The fitted normal Gaussian function can be transformed into a function which defines the laser power with respect to time by multiplying the fitted function by Eₚ/Aₚ. Here Ep is the energy per pulse given by Eₚ=P_{avg}/R, where P_{avg} is the average power of the laser beam, and R is the repetition rate of the laser. Thus:

$$P ( t ) = \frac{{E}_{p}}{{A}_{p}} g ( x ) = \frac{{E}_{p}}{σ \sqrt{2 π}} {e}^{- {( x - μ )}^{2} / 2 {σ}^{2}} \qquad ( 8 )$$

In the model, μ is set to 1.00×10⁻⁵ s, so the first peak occurs at 1.00×10⁻⁵ s. Shifting the pulse makes it easier to set desired output times in the model. The analytic function used to define the pulse is set to repeat every 1/R=2×10⁻⁴ s. The peak instantaneous powers for average laser powers of 3, 4 and 5 W are 1290, 1720 and 2150 W, respectively.

Numerical Modelling—Model Setup—Initial Conditions and Boundary Conditions. The initial condition is a uniform temperature distribution, T(x, y, 0)=T₀, where T₀ is the ambient temperature. The right and bottom boundaries are modeled as constant temperature boundaries where T=T₀ and assumed to be sufficiently far away from the localized pulse, centered on the top surface. A symmetry boundary condition is applied to the left boundary. The top boundary is modeled as a combined boundary condition which includes the periodic heat flux due to the laser heating, convection, and radiation. This boundary is defined as:

$$- k ( \frac{\partial T}{\partial y} ) {\vert}_{y = 0.5 mm } = q ( x , t ) - h ( T - {T}_{0} ) - {σ}_{e} ɛ ( {T}^{4} - {T}_{0}^{4} ) \qquad ( 9 )$$

where h is the forced convection coefficient, σₑ is the Stefan-Boltzmann constant and ϵ is the emissivity. Values for the heat transfer coefficient and emissivity are given in the following section. A standard value for the heat transfer coefficient for forced convection was used.

Numerical Modelling—Model Setup—Material Properties and Other Model Parameters. Material properties used in the model and other model parameters are listed in Tables 1 and 2, respectively. Solid and liquid phase properties are denoted (s) and (l), respectively. The density of the powder compact, ρ, in Table 1 is calculated as ρ=ρₛ(1−ϕ) based on the density of Bi₂Te₃, ρₛ=7857 kg/m³, and the porosity ϕ. The density for liquid Bi₂Te₃ is estimated based on data for the percent volume change of Bi₂Te₃ upon fusion.

TABLE 1
Material Properties.

| Material | Property | Symbol | Unit | Value |
|---|---|---|---|---|
| Bi₂Te₃ (s) | Absorptivity | A | — | 0.3 |
| Bi₂Te₃ (s) | Emissivity | ϵ | — | 0.66 |
| Bi₂Te₃ (s) | Porosity | φ | — | 0.15 |
| Bi₂Te₃ (s) | Density | ρₛ | kg/m³ | 6677 |
| Bi₂Te₃ (l) | Density | ρₗ | kg/m³ | 7554 |
| Bi₂Te₃ (s) | Specific Heat Capacity | C_{p,s} | J/kg · K | Cₚ (T) |
| Bi₂Te₃ | Thermal Conductivity | k_{TI}/k_{M-E} | W/m · K | See FIG. 2 |
| Bi₂Te₃ | Latent Heat of Fusion | L_{f} | kJ/kg | 151.53 |
| Bi₂Te₃ | Melting Temperature | Tₘ | K | 859 |
| Substrate (s) | Density | ρ_{sub} | kg/m³ | ρ_{sub} (T) |
| Substrate (s) | Specific Heat Capacity | C_{p,sub} | J/kg · K | C_{p,sub} (T) |
| Substrate (s) | Thermal Conductivity | k_{sub} | W/m · K | k_{sub} (T) |

Two different effective thermal conductivity values, representing approximate upper and lower bounds on the thermal conductivity of a green compact, are used due to uncertainty concerning the actual thermal conductivity of Bi₂Te₃ powder compacts and to investigate the impact of solid phase thermal conductivity on the molten pool size, shape and duration. The effective thermal conductivity of a green compact or a powder bed is strongly influenced by factors such as the packing density and the contact area between individual particles. Furthermore, some slight temperature dependence should he expected due to an increase in contact area between particles and increased radiative and convective heat transfer as temperature of the green compact or powder bed increases. The Maxwell-Eucken model was used to estimate an upper bound on powder compact thermal conductivity. The powder compact is treated as a heterogeneous porous medium comprised of air and solid Bi₂Te₃. For solid contents greater than 50%, the effective thermal conductivity of the powder compact given by the Maxwell-Eucken model is: where, k, kₛand kₐ are the thermal conductivity of the powder compact, solid Bi₂Te₃ and air, respectively. Also, a is defined as a=3 kₛ/(2 kₛ+kₐ). The Maxwell-Eucken model is used to define thermal conductivity values for temperatures less than the solidus temperature. The thermal conductivity of liquid Bi₂Te₃ is used for temperatures above the solidus temperature.

TABLE 2
Model Parameters

| Parameter | Value | |
|---|---|---|
| Convection coefficient, h | 10 | W/m² · K |
| Laser Repetition rate, R | 5 | kHz |
| Time between pulses, τ | 200 | μs |
| Beam Radius, ω | 140 | μm |
| Average laser power, P_{avg} | 3, 4, 5 | W |
| Scan speed, υ | 40 | mm/s |

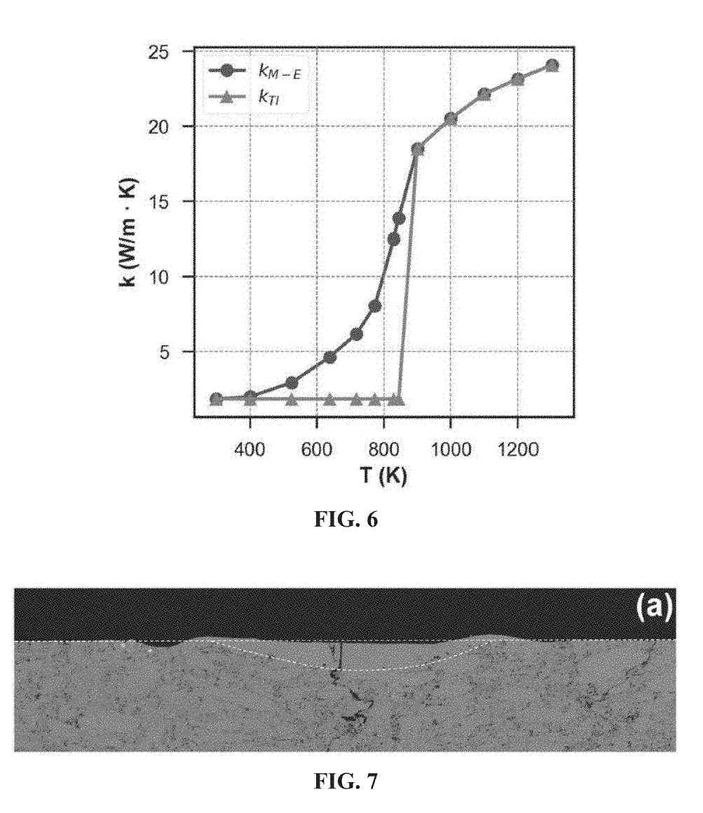

A lower bound on the thermal conductivity of the powder compact was approximated by treating the thermal conductivity of the powder compact as temperature-invariant. The room temperature value of thermal conductivity, computed via the Maxwell-Eucken model, was used for all temperatures less than the solidus temperature. FIG. 6 is a graph illustrating temperature variant and invariant solid phase thermal conductivity of Bi₂Te₃ powder compacts used in the model. The subscript TI refers to the temperature invariant solid phase thermal conductivity model case, and M-E refers to the temperature dependent solid phase thermal conductivity model case treated via the Maxwell-Eucken model. Simulations were performed for each of the thermal conductivity model cases at P_{avg}=3, 4 and 5 W.

Results and Discussion—Size and Shape of the Processed Region. Polished cross-sections of the processed region were inspected via scanning electron microscopy. FIGS. 7-9 show SEM images of the polished cross-sections for samples processed at 3, 4 and 5 W, respectively (scale bar=100 μm). No significant subsurface consolidation was observed in the samples processed at 1 and 2 W. Melting and solidification occurred in a small region near the surface of the powder compact. There is no observed heat affected region at the boundary between the processed region and unprocessed region. The transition between the melted region and surrounding powder compact is very distinct. The short pulse duration, high intensity beam produced highly localized heating near the surface of the compact. The depth, d₁, and width, w₁, of the processed region are listed in Table 3, below. Additionally, the depth d₂ and width w₂ of the processed region measured at the powder compact surface are also listed in Table 1. The width at the surface, w₂, is roughly a measure of the width of the semi-circular subsurface portion of the processed region. These two measurements roughly quantify features such as the partially ejected material present at the edge of the processed region and the small depression near the center of the processed region. The measurements are diagrammed in FIG. 8. All measurements are taken from FIGS. 7-9 and were made using ImageJ. The values presented in Table 3 are averages of five separate measurements. The standard deviation in all width and depth measurements were roughly 5 μm and 1 μm, respectively.

TABLE 3
Processed Region Size Measurements.

| P_{avg} (W) | w₁ (μm) | w₂ (μm) | d₁ (μm) | d₂ (μm) |
|---|---|---|---|---|
| 3 | 264 | 206 | 20 | 22 |
| 4 | 392 | 290 | 27 | 35 |
| 5 | 471 | 395 | 53 | 59 |

At 3 W the processed region is only 20 μm deep, and the overall width, 264 μm, is slightly less than the laser beam diameter of 280 μm. The depth measured from the surface of the powder compact and depth of the processed region are nearly the same; however, the width measured at the surface of the powder compact and the overall width differ by roughly 60 μm. The processed region surface is relatively at with small regions of partially ejected molten material at the edges of the processed region. The partially ejected material is the main contributor to the difference in the two width measurements, w₁ and w₂. As the average power of the laser increases, the depth and width of the processed region grow. The amount of partially ejected material at the edge of the processed region increases, and a depression in the processed region relative to the surface of the powder compact forms. This can be seen both qualitatively in FIGS. 7-9; the differences between d₁ and d₂ as well as between w₁ and w₂ increased as the average power increased. The depressed central region and partially ejected material on the edge are likely the product of partial melt ejection constrained by surface tension forces in the molten liquid. A piston-like mechanism drives melt ejection due to a parabolic recoil pressure profile on the free surface of the molten liquid, pushing the melt out from under the laser beam. For high intensity laser irradiance, this mechanism of melt ejection can lead to splatter or deep cuts in the material and is a common mechanism in laser drilling and cutting.

Melting with significant subsurface depth, on the order of the typical layer thickness in SLM, 20-100 μm, was observed in Bi₂Te₃ powder compacts processed via pulsed laser for a narrow window of average powers. At lower irradiances, no significant depth of melt was achieved; higher irradiances resulted in excessive splatter and cutting. This narrow window may pose challenges when trying to optimize processing parameters to create monolithic, fully dense thermoelectric material parts via pulsed laser. The low scan speed, 40 mm/s, may have contributed to the small processing window. The sensitivity of the melt depth of silicon to the scan speed of a continuous wave laser beam: melt depth decreases with increasing scan speed. With a different pulsed laser, parameters such as repetition rate and pulse duration could be adjusted to achieve a greater depth of melt over a wider window of average powers.

Results and Discussion—Morphological Features of the Processed Region. FIGS. 7-9 show microcracks and a lack of visible porosity. Microcracks are present in all processed samples. Microcracking is a commonly observed phenomenon in SLM; it arises from residual stress caused by the large temperature gradients, favoring crack propagation from the surface. The heated top layer expands, but it is constrained by the cooler lower layers leading to compressive strains. Similarly, thermal contraction gives rise to tensile strains during cooling. Preheating the substrate or post-process heat treatment reduce residual stress associated with steep temperature gradients in SLM.

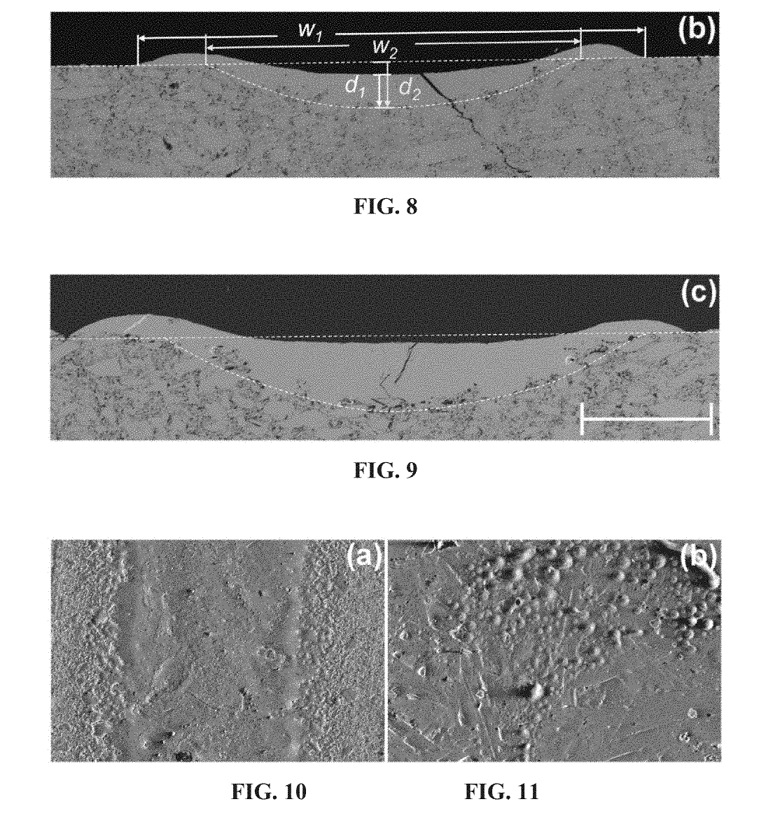

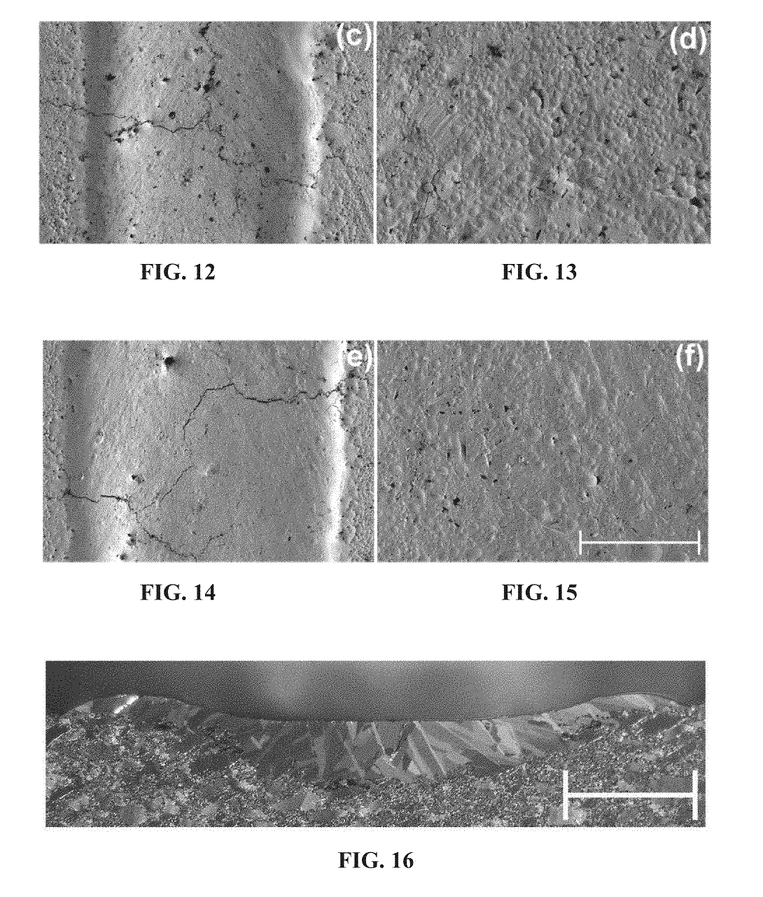

FIGS. 10-11 are surface SEM images for the samples processed at an average power of 3 W at 750× and 5000×magnifications, respectively. FIGS. 12-13 are surface SEM images for the samples processed at an average power of 4 W at 750× and 5000×magnifications, respectively. FIGS. 14-15 are surface SEM images for the samples processed at an average power of 5 W at 750× and 5000× (scale bar=30 μm) magnifications, respectively. Micro-cracking was also observed in surface images of the processed region. Micro-cracking appears slightly more pronounced at higher laser average powers of 4 and 5 W, as seen in FIGS. 12 and 14, likely due to the larger temperature gradients present during processing at higher laser average powers. In addition to microcracking, evidence of balling and surface porosity is present in all the images. Balling refers to small, microsized balls, on the order of 5-10 μm in diameter, observed on the surface. Balling appears more prevalent in the samples processed at higher average powers, 4 and 5 W. Balling in the samples processed at 4 and 5 W appears flattened relative to the balling present in the sample processed at 3 W. The flattening is likely caused by increased recoil pressure during processing at higher average powers. There is also surface porosity present in the samples processed at 4 and 5 W. Most of the surface porosity consists of cave-like spherical surface pores on the order of 5-10 μm in diameter. Melt pool instabilities, driven by recoil pressure and Marangoni convection, may be a possible cause of surface porosity, melt splashing and other irregular surface features observed in laser melting.

Results and Discussion—Microstructure of the Processed Region. The microstructure of the processed region was observed via polarized light microscopy. FIG. 16 is a polarized light micrograph showing the polished cross-section of the sample processed at P_{avg}=5 W (scale bar=100 μm). A very fine microstructure with thin, tall columnar grains is observed. The microstructure exhibits some qualitative evidence of preferred orientation near the center of the processed region oriented towards the center of the top surface, coinciding with the location of the peak intensity of the Gaussian beam. Strong thermal gradients in SLM can drive crystal growth along specific orientations leading to crystallographic textures in the microstructure. Microstructure tuning is an important area of investigation for future efforts concerning SLM of thermoelectric materials. Grain boundaries serve as scattering sites for phonons, so SLM may open the door for thermal property tuning via microstructure control. Microstructure control can be achieved by altering scanning parameters (e.g., hatch spacing, scan speed, or build direction), changing input laser energy density, preheating the substrate, or employing a pulsed laser source instead of a continuous wave laser source.

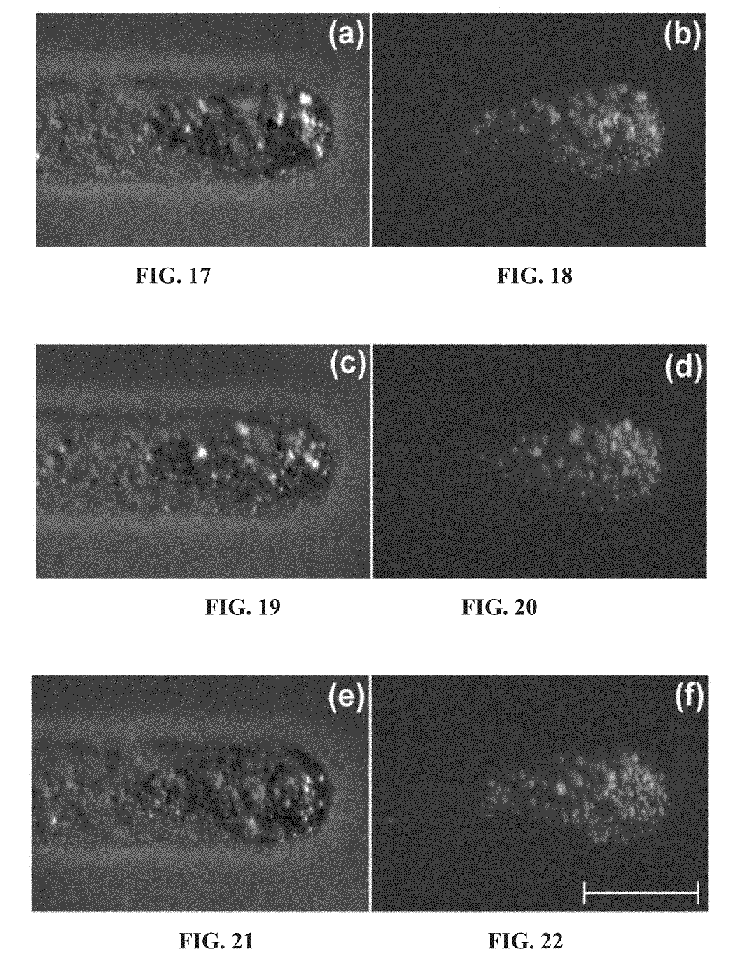

Results and Discussion—In-situ Observations of the Molten Pool. FIGS. 17, 19, 21 show in-situ images of the molten pool at three separate times, 4.8, 50 and 194.8 μs after the sintering laser pulse. FIGS. 18, 20 and 22 (scale bar=1 mm) are composite images of the stroboscopic imaging data. The repetition rate used in all experiments was 5 kHz, corresponding to a time between pulses of 200 μs, so the images represent molten pool evolution over a given pulse. The full video of stroboscopic imaging data is provided in the supplementary data. The processed composite images show the root mean square (RMS) of the difference in pixel intensity between frames for ten consecutive frames of stroboscopic imaging data centered around 4.8 μs (b), 50 μs (d), and 194.8 μs (f) after the laser pulse. In order to minimize the impact of variations in processing conditions between pulses, data were used from images taken near the center of the sample, far from the boundaries of the compact, and well after the translation stage reached a constant velocity. The RMS value is used since it allows systematic detection of the liquid region due to signal fluctuations in that region, as opposed to the solidified region where the signal is constant (RMS=0). The bright regions of the composite images correspond to a large RMS value while the darker regions correspond with a small RMS value.

Both the processed composite images and the actual stroboscopic imaging data show a roughly teardrop shaped molten pool and qualitatively little change in the molten pool width over the course of a pulse. However, there does appear to be a small decrease in molten pool length over the course of a single pulse. The qualitative observation of a constant molten pool width over the course of a single pulse is an important observation regarding validation of the numerical model, discussed below, particularly regarding the choice of solid phase thermal conductivity used to model the powder compact. This result presumably holds true for the normal processing parameters (smaller beam diameter and lower laser power) used in the main processing experiment since both the scaled-up, in-situ imaging and main processing experiment were conducted at a similar linear energy density (L). This assumption warrants further investigation, since the scaling parameter, linear energy density (L), only accounts for a similar power per unit area deposited by the laser in the both the imaging and normal processing experiments. Boundary effects, the increased surface to volume ratio of the molten pool, and more complex physics, such as Marangoni flow, are not accounted for in this scaling parameter. Understanding scaling laws in pulsed laser melting could be a key effort for future work regarding in-situ imaging of the molten pool. In addition to efforts to resolve smaller and smaller molten pools and molten pool features using stroboscopic imaging, a better understanding of the proper scaling between experiments conducted at different laser diameters, powers and scan speeds could enable better studies of molten pool features. To the best of the authors' knowledge, this is the first demonstration using stroboscopic imaging to make in-situ observations of the molten pool in SLM via pulsed laser. The process could potentially be used to investigate complex fluid physics associated with pulsed laser melting and even image the vapor phase above the sample.

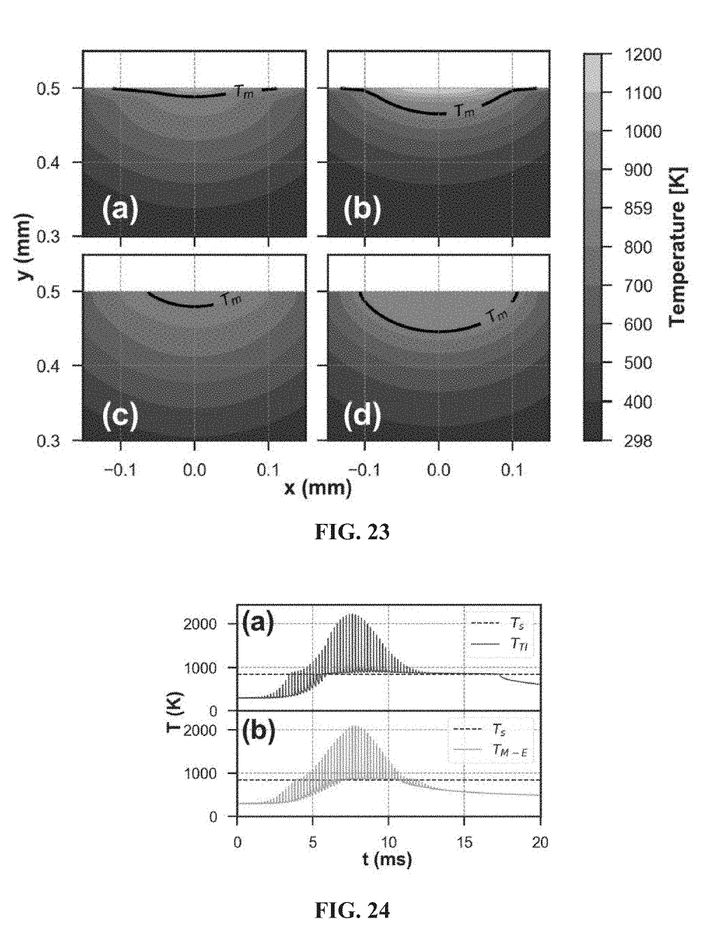

Numerical Modelling—Maximum Width, Depth and Temperature of the Molten Region. FIG. 23 shows the temperature contours when the maximum width and depth of the molten region are observed in the numerical simulation for 5 W average laser power. The maximum width and depth for the numerical simulations using the Maxwell-Eucken (M-E) model for the Bi₂Te₃ solid phase thermal conductivity are shown in FIGS. 23(a) and 23(c), respectively. While maximum width and depth for the numerical simulations using the temperature invariant (TI) Bi₂Te₃ solid phase thermal conductivity are shown in FIGS. 23(b) and 23(d), respectively. Temperature contour images were assembled by mirroring the simulation results across the symmetry plane in the model. The contour corresponding to the solid-liquid interface is indicated by the line labeled Tₘ.

The peak width occurs at the same time, t=7.815 ms, for both the TI and M-E model cases and corresponds to the pulse just after the Gaussian beam is centered over the modeled plane. The peak depth for the TI model case occurs at t=10.205 ms, later then the peak depth for the M-E model case, which occurs at t=8.870 ms. The TI model case has a larger molten width (265.8 μm) and depth (54.4 μm) than the molten width (222 μm) and depth (20.4 μm) observed for the M-E model case. The temperature gradient in the TI model case is larger. The location of similar temperature contours are more closely packed near the top surface of the powder compact in the TI model case, as seen in FIGS. 23(b) and 23(d).

FIG. 24 shows the evolution of the peak temperature observed in the model over time. Results from the TI model case are shown in FIG. 24(a) and for the M-E model case in FIG. 24(b). The total model duration in both cases was 20 ms. The peak temperature observed, 2221 K, in the TI model case is greater than the peak temperature, 2093 K, in the M-E model case. The overall molten pool duration was 11.52 ms for the TI model case and 3.52 ms for the M-E model case.

Overall, the lower solid phase thermal conductivity of the TI model case leads to higher peak temperatures, stronger temperature gradients and larger, longer duration molten pools than the M-E model case. Heat supplied by the laser during melting, as well as latent heat liberated during resolidification, needs to be continuously carried away from the small region near the surface of the sample to the metallic substrate. Typically, in SLM, thin layers of powder, on the order of 20-100 μm thick are placed on top of an already solidified layer which acts as the substrate. The thickness and the low thermal conductivity Bi₂Te₃ powder compact likely contribute to the size and duration of the numerically modeled molten pool, particularly for the TI Bi₂Te₃ solid phase thermal conductivity model case.

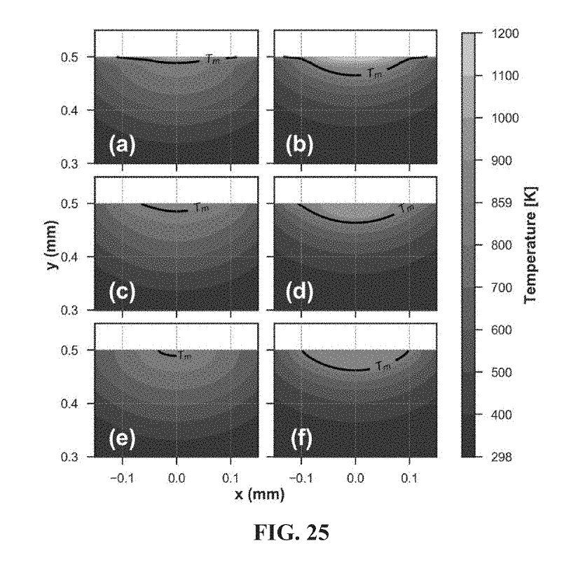

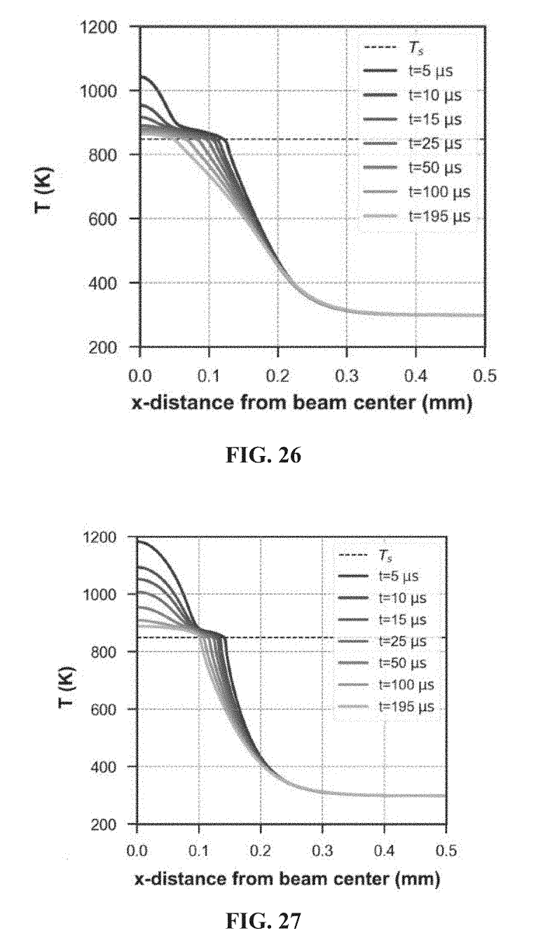

Numerical Modelling—Temporal Evolution of the Molten Region. FIG. 25 shows the numerically simulated molten pool size and shape for a laser average power of 5 W, at 5, 50 and 195 μs after the pulse at t=7.815 ms. The M-E model case is shown in FIGS. 25(a), 25(c), and 25(e), and the TI model case in, FIGS. 25(b), 25(d), and 25(f). For both cases there is a strong temperature gradient present at only 5 μs after the pulse. The peak temperatures, 5 μs after the pulse, are 1183 K and 1043 K, for the TI and M-E model cases, respectively. At 50 μs after the pulse the molten pool size for the M-E 310 model case has significantly decreased, and by 195 μs after the pulse, just 5 μs before the next laser pulse, the molten pool has nearly resolidified. For the TI model case, the molten pool only marginally resolidifies by 195 μs after the pulse. The change in molten pool width is shown in FIGS. 26 and 27. The M-E model case is shown in FIG. 26 and the TI model case in FIG. 27. The width of the molten pool for the M-E model case decreases from 222 μm at 5 μs after the pulse to 66 μm at 195 μs after the pulse; the width for 315 the TI model case decreases from 266 μm to 195 μm over the same time period. Results from the model case using temperature-invariant solid phase thermal conductivity are more consistent with the experimentally observed molten pool size and the in-situ observations of the molten pool which show little to no qualitative change in the molten pool width. The sensitivity of the model to the powder bed thermal conductivity is discussed further in the following section.

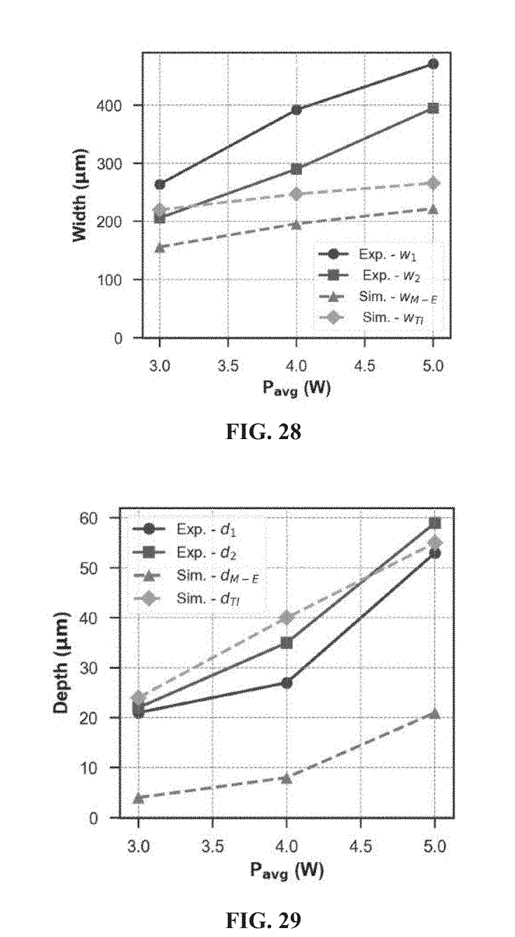

Numerical Modelling—Comparison with Experimental Results. FIG. 28 compares the measured width of the processed region, both w₁ and W₂, to the maximum width of the molten pool observed in the numerical model for both model cases, w_{M-E} and w_{TI}. The observed overall width, w₁, exceeds the predicted molten pool width. The same is true for the width of the semicircular subsurface processed region, w₂, except at P_{avg}=3 W. Here the modeled width for the TI case, 220 μm, exceeds the width of semi-circular subsurface portion of the processed region which is 206 μm. FIG. 29 compares the measured depth of the processed region, both d₁ and d₂, to the maximum depth of the molten pool observed in the numerical model for both model cases, d_{M-E} and d_{TI}. The maximum molten pool depth for the M-E model case is significantly less than the observed depth of the processed region for all three modeled laser average powers. The maximum molten pool depth observed for the TI model case slightly exceeds both the actual depth of the processed region, d1 and the depth of the processed region measured from the compact surface, d₂, for P_{avg}=3 and 4 W. At P_{avg}=5 W the depth of the molten region observed in the TI model case falls in between the values of d₁ and d₂.

Both the M-E and TI model cases underestimate the width of the processed region, and the increase in maximum molten pool width with increased laser average power occurs at a slower rate in the model than observed experimentally. The maximum molten pool depth in the M-E model case is significantly less than the observed experimental depth while the maximum molten pool depth, observed in the TI model, case agrees much better with the experimentally observed values. The processed region (FIGS. 7-9) shape has features, such as the partially ejected material at the edge and slight depression near the center of the top surface of the processed region, which are not captured by the model.

Neglected physics in this simplified thermal model are likely the reason for the differences between the observed processed region width and numerically modeled molten pool. This includes evaporation, recoil pressure and Marangoni convection. Marangoni convection is driven by large surface tension gradients which arise due to the temperature gradients present in the melt. A negative dependence of surface tension on temperature drives wider and shallower molten pools, while a positive dependence drives deeper, narrower molten pools. The high intensity of nanosecond pulsed laser beams can lead to rapid vaporization of the condensed matter phase. The net evaporative flux and collisions from condensing particles give rise to a back-pressure, called recoil pressure, on the free-surface of the molten liquid. Recoil pressure can produce strong tangential convective melt flows due to a pressure gradient that arises from higher surface temperatures at the center of the Gaussian laser beam; it introduces strong curvature of the melt surface which can further alter fluid flow. Recoil pressure can drive deeper melt penetration, flatter and wider molten pools and melt ejection. Including pertinent gas and liquid phase phenomena will require significant effort to characterize important gas and liquid phase material properties for Bi₂Te₃ and other common thermoelectric materials since these properties are not readily available and may never have been characterized.

The simplified 2D model may also contribute to the observed differences between model and experiment. The 2D model neglects out-of-plane heat transfer and the impact of the thermal front which propagates and arrives ahead of the laser beam. These two factors tend to counteract each other, so the impact of using a simplified 2D model on the overall shape and size of the mimetically modeled molten region needs further investigation.

Despite the simplified model, the TI model case still shows decent agreement with the observed processed region depth, and the TI model case predicts the experimentally observed size and temporal evolution of the molten pool better than the M-E model. The temperature invariant thermal conductivity is a more accurate choice than the Maxwell-Eucken model for modeling the solid phase thermal conductivity of a green compact. Since the packing density and the contact area between individual particles contribute to the effective thermal conductivity, the temperature invariant model may be a better approximation when extending this model to loose powders instead of higher packing density green compacts. While the temperature-invariant model appears to be a good approximation for Bi₂Te₃ green compacts, some slight temperature dependence of the effective thermal conductivity should be expected. As temperature increases so does the contact area between particles and the amount of heat transferred between particles.

The contrast between molten pool size, shape and duration determined by the M-E approach compared to the TI approach may offer some useful insight regarding laser processing of thermoelectric materials. These differences are driven by the strong temperature dependence of Bi₂Te₃ thermal conductivity in the M-E model case relative to the TI model case. Such strong temperature dependence of thermal conductivity is not present in materials commonly used in SLM, such as metals. The TI model case shows better agreement with experimental results and represents a lower bound on the Bi₂Te₃ thermal conductivity that may be best suited to model loose powders. The M-E model case may be a better representation of porous solids, such as the partially porous processed region, in SLM, after at least one layer has been melted. In SLM, the substrate is the primary heat sink; it usually consists of a metal plate and the previously solidified layers. Controlling the substrate temperature and thus altering the thermal conductivity of previously solidified layers may be an interesting degree of freedom in SLM of thermoelectric materials. Control of substrate temperatures has been used to reduce residual stresses present in SLM of metals as well as to alter cooling rates and microstructure in SLM of metallic glasses. Altering substrate temperatures to control solidification rates has also been used in other fields such as laser annealing of silicon thin films.

Experimental Study #2—Selective Laser Melting (SLM) of Bi₂Te₃ with a Continuous-Wave Laser

Experimental. The selective laser melting process was conducted with a custom-built tool to enable flexibility in materials processed. (Commercial tools are typically specified for only a few materials such as stainless steel and titanium while our modifications allow for maximum flexibility for research purposes.) Bi₂Te₃ powders (99.98% trace metal basis, Alfa Aesar) were evenly spread and flattened inside a thin stainless steel ring (McMaster-Carr, part number 97022A331) which serves as the powder bed container for one layer. For each layer, a laser scanned the surface in a pre-designed pattern. The laser processing was done in a laser melting enclosure which was purged with N₂ gas. An oxygen sensor was used to monitor the oxygen level through the experiment, and the oxygen level was maintained at 4% or less. The laser is a 1070 rim diode-pumped Ytterbium fiber laser, operating in the continuous wave mode with output power up to 100 W (IPG Photonics, YLR-Series). The system is equipped with a mid-power scanner (IPG Photonics, P30 series) to control laser beam position. After one layer was processed, another ring was added on top and a second powder layer was deposited inside the new ring; then the laser repeated the scan pattern. The stacked rings eventually formed a sample holder for the desired. number of additive layers. The thickness for each layer was about 150 μm. After 8 layers, an ingot in the desired shape with a thickness over 1 mm was formed.

Control samples were made using a hot press. Two sets of the original Bi₂Te₃ powders (approximately 2 grams each) were hot pressed at 500° C. in a nitrogen environment at 150 MPa. The first powder sample was hot pressed for 10 minutes and resulted in a sample density of 6.1 g/cm³ (˜79% relative density), and the second, hot pressed for 3 hours, resulted in density of 7.1 g/cm³ (˜92% relative density)

Phase identification was conducted with X-ray diffraction, and sample imaging was done with scanning electron microscopy. The SLM-processed samples were first gently crushed and ground into powders using a mortar and pestle. Then powder XRD was performed with a Rigaku Miniflex II Cu—Kα X-ray diffractometer. The SLM-processed samples were cast in epoxy resin, ground and polished to reveal the cross section along the build direction. The surface was polished down to a 0.04 μm finishing using an Allied High Tech Multiprep polishing system. The SEM micrographs for the cross section were then obtained with an FEI Tales Teneo LV FEG scanning electron microscope.

The density was measured using a Mettler Toledo XS204 density determination kit, based on Archimedes' principle. The sample was first weighed in air; then it was completely immersed in liquid and weighed again. The density was determined through the formula:

(A/(A−B))×(ρ₁−ρ₂)+ρ₂ (10)

where A is the sample weight in air, B is the sample weight in liquid, ρ₁ is density of liquid, ρ₂ is the density of air (0.0012 g/cm³). Technical grade distilled water was used; it has a density of 0.99764 g/cm³ at the measured temperature of 22.7° C.

The absolute Seebeck coefficient, S, and electrical resistivity, ρ, were characterized in the in-plane direction. At room temperature, steady-state S and four-probe electrical resistivity, ρ, were measured using a custom-designed probe, calibrated using standards and compared with a separate probe, with an uncertainty of approximately 15% for both S and ρ. The high-temperature S and ρ were measured from 50° C. up to 500° C. in a He environment using a commercial Linseis LSR-3 Seebeck coefficient and electric conductivity measurement unit (Linseis Gmbh, Selb, Germany).

The specific heat Cₚ and thermal diffusivity λ were measured in the cross plane direction from 30° C. to 500° C. in vacuum using a commercial Linseis Laser Flash Analyzer (LFA 1000) with a Diode-pump IR Laser and LN₂-cooled IR detection system (Linseis Gmbh, Selb, Germany). The thermal conductivity k was determined using k−Cₚ·ρₘ·λ, where ρₘ is the mass density. The measured density value at room temperature was applied for all temperatures to calculate thermal conductivity. The temperature-dependent thermal properties were measured in the direction perpendicular to that in which the Seebeck coefficient and electrical resistivity were measured due to restrictions in the measurement technique and sample geometry. Any anisotropy in thermal conductivity is not captured in the characterization results presented here. This is a common limitation encountered in thermoelectric property characterization, particularly for thin/thick film or small samples.

Results and Discussion. The loose powders of Bi₂Te₃ were successfully processed in a layer-by-layer approach to produce a final disc-shaped part which was 8 mm in diameter and over 1 mm thick. The disk was formed with eight layers of powder with each layer about 150 μm thick. To form the disk, the optimal laser power, spot size, scan speed, and hatch distance were 25 W, about 50 μm, 500 mm/s, and 37.5 μm, respectively. These parameters led to a laser energy density E of 1.3 J/mm², according to

$$E = \frac{p}{vh} ,$$

where p is laser power, v is the scan speed, and h is the hatch distance. The processing parameters were chosen such that the energy density was high enough to melt each layer thoroughly and low enough to avoid sample bending.

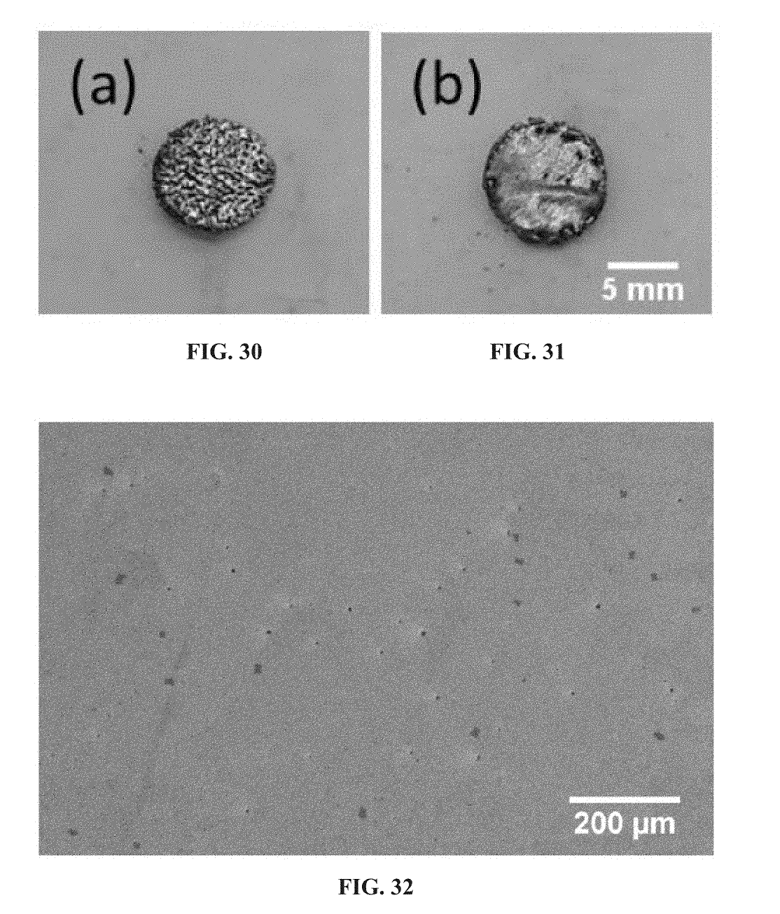

Improving density (or minimizing porosity) of the produced parts is a major challenge for selective laser melting, regardless of whether it is applied to metals, ceramics, or semiconductors. Size distribution and particle morphology affect the powder flow, and the powder's ability to flow influences the packing of the powder bed, which in turn affects density (or porosity). For the case of Bi₂Te₃, the as-received powders have a large size distribution ranging from below 10 μm larger than 150 μm, and the powder particles generally have irregular shapes (i.e., aspherical, high aspect ratio). The large size distribution and irregular particle shapes cause mechanical interlocking and lead to voids which cause low packing density of the powder bed before melting. Consequently, the Bi₂Te₃ disks formed were not fully dense, as shown in FIG. 30. In order to increase density, we increased the laser power from 16 W to 25 W (changing the energy density from 0.85 J/mm² to 1.3 J/mm², respectively) with other parameters the same, resulting in an effective improvement of the density from 6.27 g/cm³ to 6.81 g/cm³. The standard value of density for Bi₂Te₃ is 7.74 g/cm³; therefore, the relative density was increased from about 81% to about 88% by adjusting the laser power. A comparison of the samples from low and high energy density is shown in FIGS. 30-31 where optical images of two thermoelectric material ingots (each 8 mm diameter and over 1 mm thick) made of commercially available Bi₂Te₃ powder using a layer-by-layer selective laser melting approach. The laser processing parameters were adjusted to increase the relative density: FIGS. 30—16 W of laser power resulted in a relative density about 81%, and FIGS. 31—25 W of laser power resulted in a relative density about 88%.

The high density sample (shown in FIG. 31) was further analyzed to demonstrate the quality of melting in the SEW processing. FIG. 32 is a scanning electron micrograph polished cross-section of the SLAT processed Bi₂Te₃ sample, in-plane along the build direction (perpendicular to the laser scan direction). Each layer is about 150 μm thick. No separation between adjacent layers was visible across the entire surface. The surface features some spherical pores, and the majority of the pores are approximately 5 μm or larger in diameter. Spherical pores are generated from gas trapped during rapid solidification or keyhole instability and collapse. This sample's relative density, 88%, is comparable to the control samples manufactured using hot pressing on Bi₂Te₃ (92% relative density), suggesting the fusion of powders was quite successful through the SLM process.

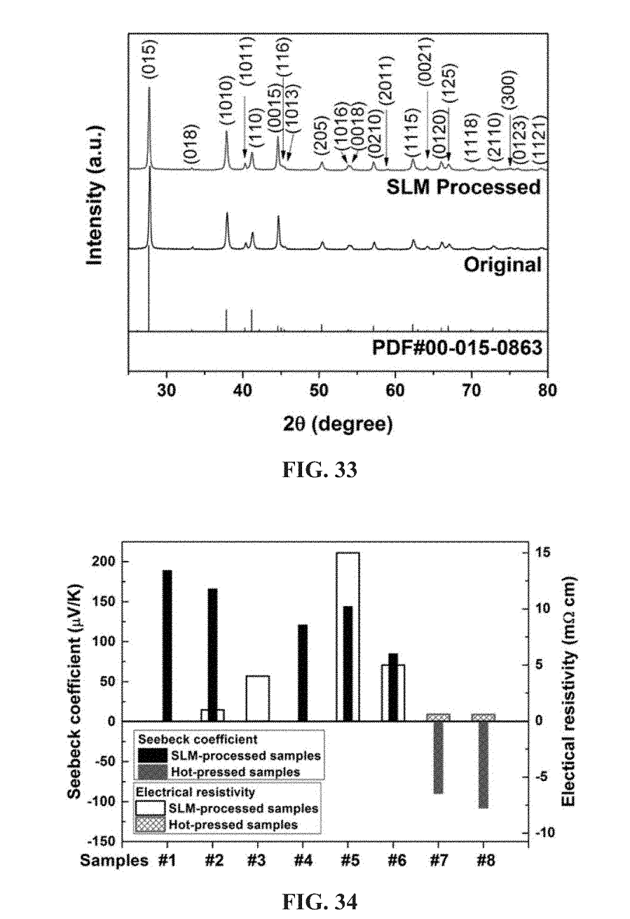

To explore any chemical or structural transition during the SLM processing, the processed samples were compared to unprocessed control samples using powder XRD. The results presented in FIG. 33 indicate that the two spectra are almost identical in the measured range, and no clear new phases were observed. Both spectra are well-matched with the database values for Bi₂Te₃ (PDF #00-015-0863), suggesting the SLM process preserved the structure for Bi₂Te₃. This result is consistent with the Bi—Te system's phase diagram where the only possible phase crystallized from the liquid phase at 60 at % of Te is Bi₂Te₃ at 585° C. XRD peak intensity differences for Bi₃Te₃ from spark plasma sintering, rolling, and forging were previously reported and interpreted as crystallographic preferred orientation changes. However, our results do not indicate a change in preferred orientation. We did notice XRD intensity differences from coarse powders crushed from RAI processed samples, indicating a lack of random orientation. However, continuing to grind samples to fine powders led to intensities which were well-matched to the control samples, suggesting the SUM process does not influence the intrinsic anisotropy for Bi₂Te₃.

The thermoelectric and electrical properties of the SLM-produced samples were also characterized. The room temperature Seebeck coefficient, S, and four-probe electrical resistivity, ρ, were measured in the in-plane direction using a custom-designed vacuum probe, as described above. The range of S and ρ values are 85-189 μV/K from five samples and 1-15 mΩ·cm from four samples at room temperature, respectively, with the majority falling between 144-189 μV/K and 1-5 mΩ·cm. A summary of the Seebeck coefficient and electrical resistivity values is shown in FIG. 34. In FIG. 34, samples 1-6 are the SLM-processed samples, and samples 7-8 are fabricated through hot-pressed method on pristine powders. For the sample 4, the powder compact was made from loose powders via compression under a uniaxial pressure of about 300 MPa, and the resulting round disks were about 0.5 mm thick and had a diameter of 6 mm. The processing parameters for each sample are shown in Table 4. The measured values vary from sample to sample, and the variation is possibly related to varying defect conditions (as discussed below) which are introduced from the melting and solidification process. The aspherical powder particle morphology leads to variation in the surface condition of each powder bed layer, so there may be a slight variation in the density and porosity of the produced samples. These geometric variations affect the calculations of intrinsic physical properties since extrinsic properties are measured (e.g., electrical resistivity is extracted from a measurement of electrical resistance). Our results are consistent with reported experimental values, which range from 130 μV/K to 260 μV/K for Seebeck coefficient and 0.6 mΩ·cm to 2.5 mΩ·cm for electrical resistivity. For example, our sample with room temperature S and ρ values of 166 μV/K and 1 μmΩ·cm, respectively, is in good agreement with the reported values of 160 μV/K and 0.7 mΩ·cm on regular p-type Bi₂Te₃ materials.

TABLE 4

| | | | Resistivity |
|---|---|---|---|
| Sample | Processing Conditions | Seebeck (μV/K) | (mΩ · cm) |
| 1 | 25 W, 500 mm/s, 37.5 μm | +189 | — |
| 2 | 25 W, 500 mm/s, 37.5 μm | +166 | 1 |
| 3 | 20 W, 500 mm/s, 37.5 μm | — | 4 |
| 4 | 20 W, 650 mm/s, 50 μm | +121 | — |
| 5 | 25 W, 500 mm/s, 37.5 μm | +144 | 15 |
| 6 | 25 W, 500 mm/s, 37.5 μm | +85 | 5 |
| 7 | hot pressed for 10 min | −90 | 0.6 |
| 8 | hot pressed for 3 hours | −108 | 0.58 |

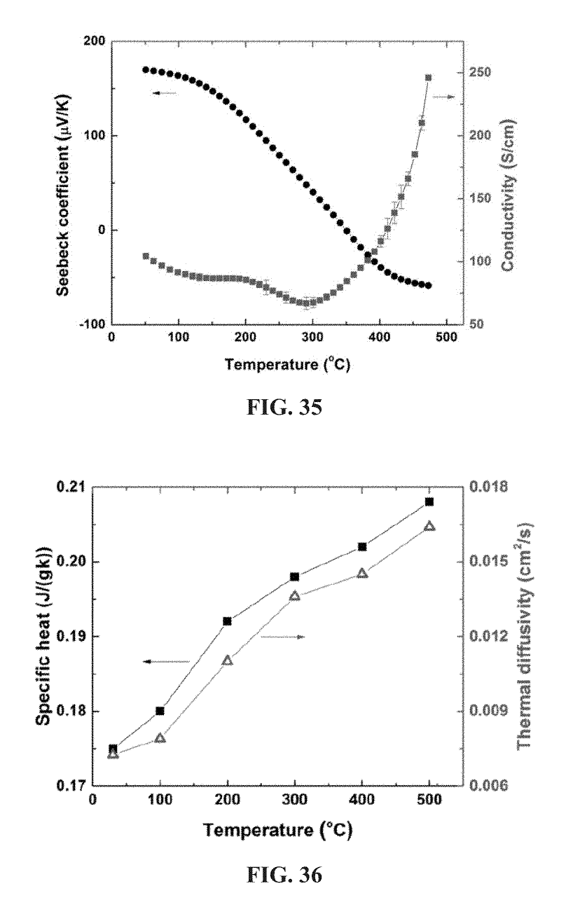

The thermal and electrical properties of the SLM-produced samples were further characterized at high temperatures. The temperature-dependent absolute Seebeck coefficient, electrical conductivity, specific heat, thermal diffusivity, thermal conductivity, and thermoelectric figure of merit ZT were characterized up to almost 500° C. in either vacuum or a helium environment using the Linseis system; the results are shown in FIGS. 35-37. The sample measured at high temperature (yielding the data in FIG. 35) was not the same sample as that measured at room temperature, but all samples were processed in the same way. The absolute value of the Seebeck coefficient is representative of the material's ability to convert thermal energy to electrical energy. As temperature increased, S first decreased from about 165 μV/K at 50° C. until it reached close to zero at about 350° C. Then, the Seebeck coefficient's absolute value increased with temperature, up to −50 μV/K at 473° C. The electrical conductivity shows a similar behavior: it first decreased, then it increased at around 300° C.

Both the thermoelectric and electrical behaviors are in agreement with previous reports. Unlike thin films which can be p-type or n-type, both single crystals and polycrystalline samples of Bi₂Te₃ are p-type at room temperature if the sample is grown slowly from a stoichiometric melt without intentional doping. There are consistent reports that Bi₂Te₃ samples undergo a p-to-n conversion while heated at high temperatures if the annealing time is short (for example, less than 4 hours). The magnitude of the negative S values increases as the temperature increases, which is consistent with our results (see FIG. 35).

Our samples fabricated via SLM show a p- to n-type transition via laser processing. Changes in electrical and thermoelectric properties can occur in binary compounds like Bi₂Te₃, depending on the thermal history of the material. Although there are different explanations, a common theme is the electrical and thermal behavior of Bi₂Te₃ depends heavily on crystalline point defects, be they vacancy defects, antisite defects or other types of point defects. Higher carrier mobility leads to larger electrical conductivity, which is consistent with our observations.

The pristine Bi₂Te₃ powders were hot-pressed to format bulk pieces at 500° C. in a N₂ environment and then measured at room temperature. Two hot press runs for 10 minutes and 3 hours each generated samples with density of 6.1 g/cm³ and 7.1 g/cm³, (about 79% and 92% relative density) respectively. The thermoelectric and electrical properties of both samples agree. The higher density sample had an S of −108 μV/K and ρ of 0.58 mΩ·cm while the other sample's properties were −90 μV/K and 0.6 mΩ·cm, respectively.

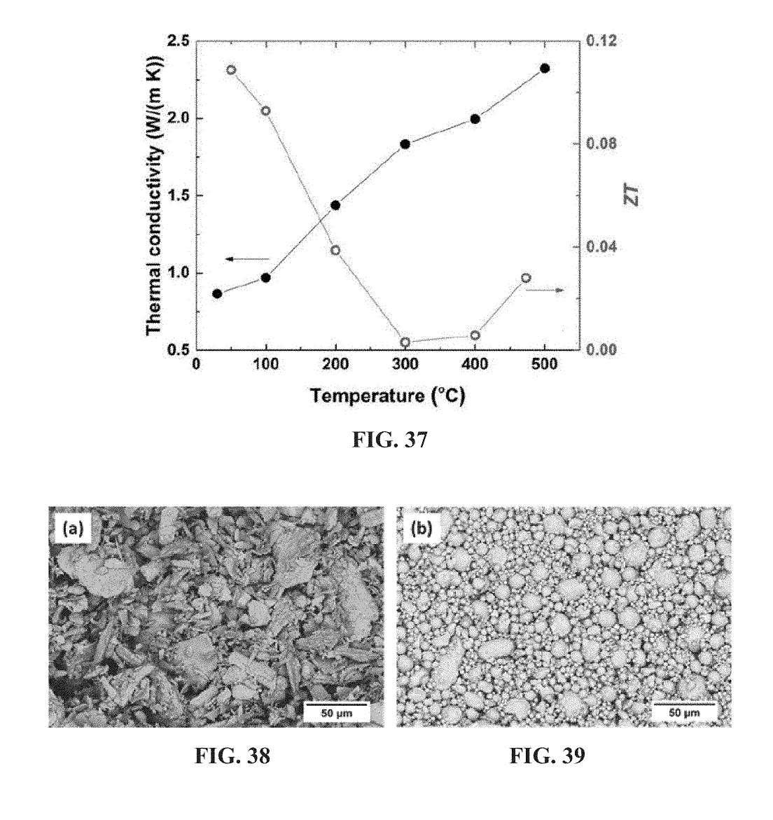

FIG. 36 shows the measured specific heat and thermal diffusivity in the cross-plane direction; both properties increase with temperature. The thermal conductivity was calculated according to k=Cₚ·ρₘ·λ, where k is the thermal conductivity, ρₘ is the density, Cₚ is the specific heat, and λ is the thermal diffusivity. The measured room temperature density value, 6.81 g/cm³, was used for calculations at all temperatures. The thermal conductivity increased with increasing temperature over the entire measurement region as shown in FIG. 37. With measured properties, the thermoelectric figure of merit ZT was calculated, as shown in FIG. 37. The behavior of ZT with temperature is primarily dominated by the electrical conductivity and the Seebeck coefficient. ZT first decreased with increasing temperature until about 300° C., slightly increased between 300 to 400° C., then increased more sharply with increasing temperature. The highest ZT value was about 0.11 at 50° C. The S and ZT values of the SLM-processed Bi₂Te₃ are in the same range as other p-type or doped n-type samples. These results indicate the SLM method is capable of producing Bi₂Te₃ samples with thermoelectric properties comparable to samples synthesized by traditional methods.

Experimental Study #3—Selective Laser Melting (SLM) of Bi₂Te₃ with a Continuous-Wave Laser to Form 3D Objects

The uncharacteristic properties of thermoelectric material powders create unique challenges for their processing via SLM. For example, spreading powder layers is more difficult for thermoelectric materials than for the more common metals or alloys. Metallic powders used in SLM have particles with spherical morphology, but the morphology of thermoelectric powder particles is highly irregular. A comparison of the particle morphology for typical stainless steel powers and the bismuth telluride (Bi₂Te₃) powders which are used in this work is shown in FIGS. 38-39. FIG. 38 is a scanning electron micrograph of a commercial Bi₂Te₃ powder which has been separated through a −270 mesh (53 μm) sieve. FIG. 39 is a scanning electron micrograph of a standard stainless steel SS340 atomized powder. As a result, the flowability for thermoelectric powders is generally worse than that for metals, and consequently, the powder bed qualities are usually different in density and surface flatness. Furthermore, the thermal conductivity and thus thermal dissipation are higher in metals than in thermoelectric materials. The powder bed properties and the light-matter interactions are very different when comparing thermoelectric, metallic or ceramic materials, so the process parameters which are suitable for metals or ceramics may be different, sometimes by a large amount, for thermoelectric materials. Due to differences in thermal and optical properties, the process parameters are also material-dependent even within the category of thermoelectric materials.

A schematic of the SLM process is shown in FIG. 3. Bi₂Te₃ dry powder (99.98% trace metal basis, Alfa Aesar) was first sieved to isolate particles smaller than 53 μm (−270 mesh) in size (FIG. 38). The powder was spread onto the building platform to form a thin, flat surface. A continuous wave 1070 nm laser (IPG photonics, YLR-series diode-pumped. Ytterbium fiber laser, equipped with a mid-power scanner, power of 0-100 W, spot size of 50 μm) was scanned over the powder surface following a pre-designed pattern composed of vectors paths. The powder rapidly, melted and then solidified from the laser heating and dissipation of heat into the surrounding powder bed. A thin layer of Bi₂Te₃ was solidified in the shape of the scanned pattern. Another layer of power was spread, and the process was repeated. Using the layer-by-layer approach, an ingot of Bi₂Te₃ with desired shape and thickness was eventually fabricated. The unprocessed powders were collected and recycled. The SLM process was conducted in an inert gas (nitrogen or argon) environment with the oxygen level no greater than 4%.

Although many factors can influence the fusion process in a laser powder bed, laser and scanning parameters as well as powder layer thickness are among the most important factors. Selecting them appropriately critically affects the formation and properties of the fabricated part. Laser melting systems often have fixed operation mode (pulsed or continuous wave), light wavelength, and beam spot size, The adjustable laser processing parameters include laser power p, scan speed v, and hatch distance h (the distance between two neighboring melted lines). Isolating the appropriate laser and powder layer parameters is closely related to the complex light-matter interaction of converting optical energy to thermal energy at the powder bed. It is common practice to use one factor to represent the combined effect of all these parameters. There are several approaches to define such a factor. These include line energy p/v (J/mm), laser energy density p/(v·h) (J/mm²), volumetric energy density p/(v·h·d) (J/mm³), or p/(v·σ·d) (J/mm³), where d is the layer thickness, and σ is the laser spot diameter. The adoption of any method usually depends on the particular laser system, properties of materials or the powder bed. For the next process mapping work, we use volumetric energy density E−p/(v·h·d) (J/mm³) to represent the overall influence from laser heating and powder layer properties.

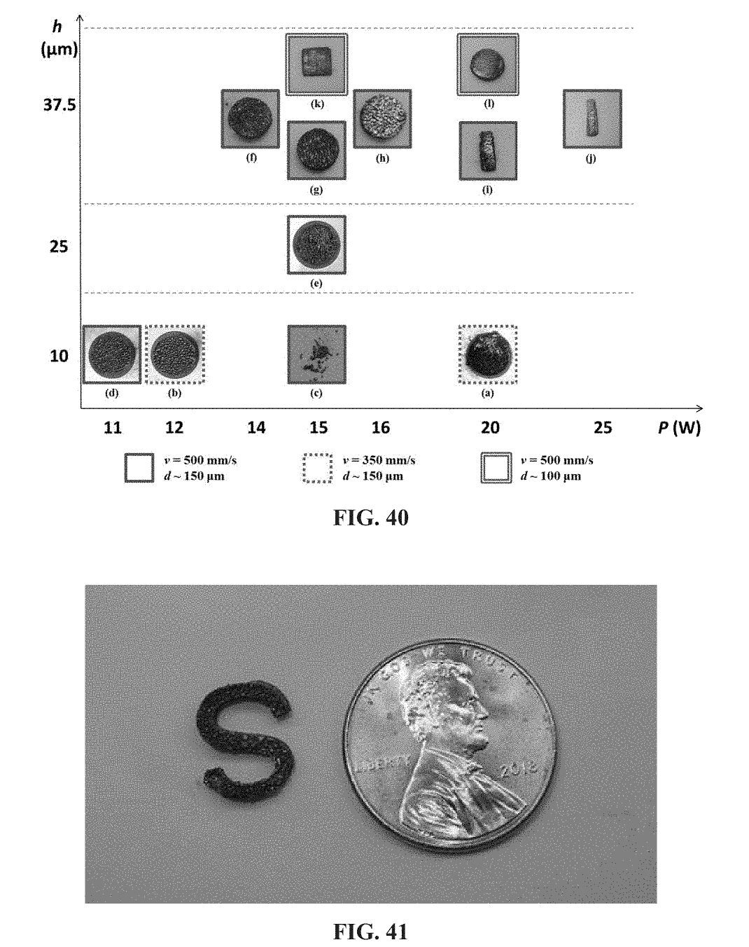

The SLM process described in FIG. 3 was used, with variations to the laser processing parameters (laser output power, scan speed and hatch distance) and the powder layer thickness, to build various 3D objects out of Bi₂Te₃. The results (samples (a)-(l)) are shown in FIG. 40, and the corresponding combinations of the parameters are shown in Table 5. Samples (a)-(h) and (l) are disks while samples (i) and (j) are rectangle-shaped, and sample (k) is square-shaped. Different shapes illustrate the advantage of the SLM process over the traditional thermoelectric part fabrication method since completely new tooling would be required to achieve different shapes with the traditional method.

Excess or deficient laser energy density results in weak mechanical strength in the SLM-produced Bi₂Te₃ parts. When excess photon energy was applied to the powder bed (samples (a)-(d)), balling phenomena were observed. This is illustrated in sample (c) where the sample readily shattered after light handling, and the original disk shape was not preserved. On the other hand, insufficient laser energy (samples (e)-(i)) led to inter-layer fusion but rough surfaces. Sample (f) shows this situation, and the sample cracked when light force was applied. When laser parameters are properly chosen, a mechanically stronger product with lower surface roughness can be achieved, as shown in Samples (j)-(l). The overall best specimens were produced with the volumetric energy density in the mid-range, approximately 9 to 11 J/mm³. The thermoelectric properties of the good Bi₂Ti₃ samples (for example, sample (j)) have been reported elsewhere.

The selective laser melting results for Bi₂Te₃ are dependent on the laser and scanning parameters as well as the powder layer thickness. FIG. 40 shows photographs of parts fabricated with different process parameters. The x-axis is the laser power, and the y-axis is the hatch distance. The axes are not linearly scaled to improve viewability. Images with solid and blue (color online) frames represent a scan speed of 500 mm/s, and those with dotted and red frames represent a scan speed of 350 mm/s. A single-line frame represents a layer thickness of ˜150 μm, and a double-line frame represents a layer thickness of ˜100 μm. The process parameters shown graphically with the images in FIG. 40 are also tabulated in Table 5. Samples (a)-(d) show the situation when excess photon energy was applied the powder bed. Samples (e)-(i) and (k) show the situation when deficient laser energy was absorbed by the powder bed. Samples (j) and (l) show the situation when laser parameters and power layer thickness are chosen close to the optimal values. Samples (a)-(h) are disks with diameter of 8 mm. Samples (i) and (j) are rectangle-shaped samples ˜3×11 mm and ˜3×14 mm, respectively. Sample (k) is square-shaped with a side length of ˜12 mm. Sample (l) is a disk with the diameter of ˜12 mm (not a scaled view compared to other disks).

The parts in samples (e) and (k) provide an interesting comparison. They were produced by similar volumetric energy density, but the resulting parts were different. The specimen in sample (k) has a slightly better surface quality and appears less porosity than the one shown in sample (e). The processing differences between these two are a smaller hatch distance h for sample (e) and a smaller layer thickness d for sample (k); the product (h·d) is the same for the two cases. This suggests that laser factors (hatch distance) and powder factors (layer thickness) have different influences on surface quality and overall sample quality although the two parameters appear to have the same influence considering only the equation for volumetric energy density. The varied influence among the key laser factors was previously reported: laser power, hatch distance, and scan speed have different impacts on the mechanical bending strength, relative density, and sample morphology. Our results on Bi₂Ti₃ thermoelectric materials compared the effect of laser factors to that of powder bed factors and complement the general conclusions that processing parameters do not influence the final parts equally in selective laser melting process. Because the volumetric energy density E cannot differentiate the influence of each parameter (p, v, h, or d), it is a useful guide but may not be a comprehensive metric for the selective laser melting process.

To further illustrate the freeform advantage of the SLM process, an “S” shaped 3D object made of Bi₂Te₃ is presented in FIG. 41. The 3D object is about 10 mm high and over 1 mm thick. This is the first demonstration of using RAI on Bi₂Te₃ powders (or any thermoelectric material) to create a form factor other than the typical shapes (square, round, or rectangular); this result experimentally confirmed the capability of SIM to fabricate thermoelectric parts of complex shapes with relatively high geometrical accuracy directly from dry powders. If the same object is to be manufactured through traditional methods, not only it will take longer time, but also roughly up to 80% of materials may be lost, while almost all un-used powders are recycled in the current study.

TABLE 5

| | | | | Layer Thickness, | Volumetric Energy |
|---|---|---|---|---|---|
| Bi₂Te₃ | Power, | Scan Speed, | Hatch Distance, | d (μm, approx. | Density, E (J/mm³, |
| Sample | p (W) | v (mm/s) | h (μm) | values) | approx. values) |
| a | 20 | 350 | 10 | 150 | 38 |
| b | 12 | 350 | 10 | 150 | 23 |
| c | 15 | 500 | 10 | 150 | 20 |
| d | 11 | 500 | 10 | 150 | 15 |
| e | 15 | 500 | 25 | 150 | 8 |
| f | 14 | 500 | 37.5 | 150 | 5 |
| g | 15 | 500 | 37.5 | 150 | 5 |
| h | 16 | 500 | 37.5 | 150 | 6 |
| i | 20 | 500 | 37.5 | 150 | 7 |
| j | 25 | 500 | 37.5 | 150 | 9 |
| k | 15 | 500 | 37.5 | 100 | 8 |
| l | 20 | 500 | 37.5 | 100 | 11 |

Experimental Study #4—Selective Laser Melting (SLM) of Half-Huesler Materials with a Continuous-Wave Laser

In this experimental study, freeform solid thermoelectric legs are formed through selective laser melting for two half-Heusler materials: ZrNiSn, and Hf_{0.3}Zr_{0.7}CoSn_{0.3}Sb_{0.7}/nano-ZrO₂ (nanoparticles ZrO₂ embedded into Hf_{0.3}Zr_{0.7}CoSn_{0.3}Sb_{0.7}). ZrNiSn powders were prepared by arc melting followed by annealing. High purity Zr foil (99.95%, Alfa Aesar), Ni powders (99.999%, Alfa Aesar), and Sn shots (99.999%, Alfa Aesar) were used as raw materials, The Ni powders were melted into small shots with sizes of 1-5 mm using arc melting (SA-200, MRF Inc., USA). The Ni shots, Zr foils, and Sn shots were loaded into a water-cooled Cu crucible for arc melting under an Ar atmosphere (SA-200, MRF Inc., USA). The congealed melts were re-melted three times after turning them over to ensure homogeneity. The obtained ingots were vacuum sealed in quartz tubes, then annealed in a box furnace at 900° C. for 168 h. After annealing, the ingots were crushed, hand grounded into fine powders (<100 μm). The phase identity and purity of samples were determined by powder X-ray diffraction (XRD, Bruker D8 Advance, Germany) using the Cu Kα radiation (λ=1.5406 Å).

SLM was performed for half-Heusler materials with a custom-built powder bed laser fusion system. The system has a continuous wave, ytterbium fiber laser (IPG Photonics YLR-100-AC-Y11; 1070 nm, 50 μm spot size) with variable power up to 100 W. The laser is scanned two-dimensionally through a mid-power scanner (IPG Photonics PGP P30-003476 Rev2) with an F-theta lens mounted on an adjustable height platform. The laser system combined with the scanner allows control of the laser scan pattern, hatch distance, and scan speed. An ingot was then constructed from dry, loose powders in a layer-by-layer fashion. In our experiments, the thickness for one layer was controlled to be about 150 μm, To process each layer, fine powders (<100 μm) were first evenly spread and flatted inside a sample container of a thin stainless steel ring; then the welding laser scanned the surface in a pre-designed pattern. In this work, the laser scanned a circle with a radius of 4 mm. After one layer of powders was deposited and selectively welded, another layer was spread and the laser repeated the scan; after 10 layers, a flat disk with a diameter of 8 mm and thickness over 1 mm was formed. The system was purged with nitrogen gas, but the oxygen level was not controlled or monitored during processing. The presence of oxygen would lead to the oxide formation.

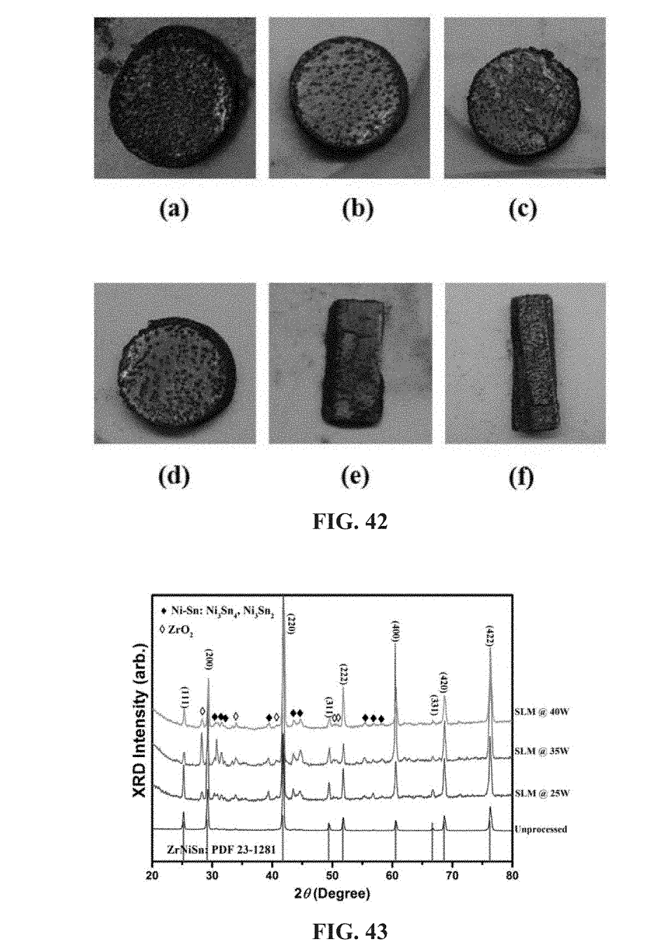

With a laser power of 20-40 W in the continuous wave mode with 350 mm/s scan speed and 5-25 μm hatch distance, ingots of ZrNiSn the desired shapes were successfully formed. FIG. 42 shows images of ZrNiSn ingots formed in this experimental study. The ingots had generally flat and porous surfaces. The density of the produced part was measured using Mettler Toledo X204 density determination kit. The SUM-produced ingot of FIG. 42(c) had a density of 4.88 g/cm³, which is about 64% of the theoretical value of 7.62 g/cm³ for ZrNiSn crystal.

In general, laser processing parameters are among the key factors which influence the formation, surface roughness, porosity, mechanical and other physical and chemical properties of the final product. However, the sensitivity to the parameters is material-related. For a laser system with a fixed operation mode, beam spot size and wavelength, the major laser processing parameters to be adjusted are laser power p, scan speed v, and hatch di stance h (the distance between two neighboring melted lines). Sometimes laser energy density E=p/vh (J/mm²) is used to represent the combined effect of the three for transferring photon energy to the powder bed. The results for adjusting laser processing parameters for ZrNiSn are shown in FIG. 42, with the corresponding combinations of the parameters shown in Table 6. The ingots shown in FIGS. 42(a)-(d) are disk-shaped with diameters of about 8 mm and thickness greater than 1 mm. The ingots of FIGS. 42(e) and 42(f) are rectangle-shaped, with dimensions of about 4 mm×10 mm and about 2 mm×11 mm, respectively; both have thicknesses greater than 1 mm. Although all six sets of parameters successfully formed the desire-shaped bulks, it is evident that those with the minimum (FIG. 42(a)) and the maximum (FIG. 42(f)) energy densities have the roughest surfaces, while those with energy densities in between (FIGS. 42(b)-(e)) have smoother surfaces. The best one was processed with an energy density of 8.57 J/mm² (FIG. 42(e)). Hence, it was possible to process the ZrNiSn material with a relatively large range of processing parameters.

TABLE 6

| | | | | Energy |
|---|---|---|---|---|
| ZrNiSn | | Scan Speed, | Hatch Distance, h | Density, E |
| Sample | Power, p (W) | v (mm/s) | (μm) | (J/mm²) |
| (a) | 25 | 350 | 25 | 2.86 |
| (b) | 30 | 350 | 25 | 3.43 |
| (c) | 35 | 350 | 25 | 4.00 |
| (d) | 40 | 350 | 25 | 4.57 |
| (e) | 30 | 350 | 10 | 8.57 |
| (f) | 20 | 350 | 5 | 11.43 |

To analyze the chemical and structural changes, powder XRD was performed for ZrNiSn samples (Rigaku Miniflex II). FIG. 43 shows the results for SINE-produced parts (which were gently ground to powders) and the unprocessed powders. All the peaks in the XRD pattern corresponding to the unprocessed ZrNiSn sample could be well indexed to the cubic half-Heusler with a space group F43-m. There are small amounts of impurity phases, such as Ni₃Sn₄, which are normally observed in ZrNiSn samples even after long annealing. The laser processing was performed at different powers of 25 W, 35 W and 40 W (all other parameters are the same: 350 m m/s scan speed and 25 μm hatch distance), and the powder XRD shows consistent results for all three powder levels. The result showed that the majority of the laser-processed powders retains the original ZrNiSn phase after laser melting; the processed material also consists of small amount of decomposition phases Ni₃Sn₄, Ni₃Sn₂, along with a ZrO₂ phase. The small amount decomposition of ZrNiSn into multiple phases including Ni₃Sn₄ and Ni₃Sn₂ was due to the incongruent melting and consistent with the complex Zr—Ni—Sn phase diagram. The laser-induced decomposition reaction during the melting process involves O₂ and may be described as: 6ZrNiSn→6Zr+Ni₃Sn₄+Ni₃Sn₇; Zr+O₂→ZrO₂. These results suggest a post-process annealing may help to complete the phase transformation.

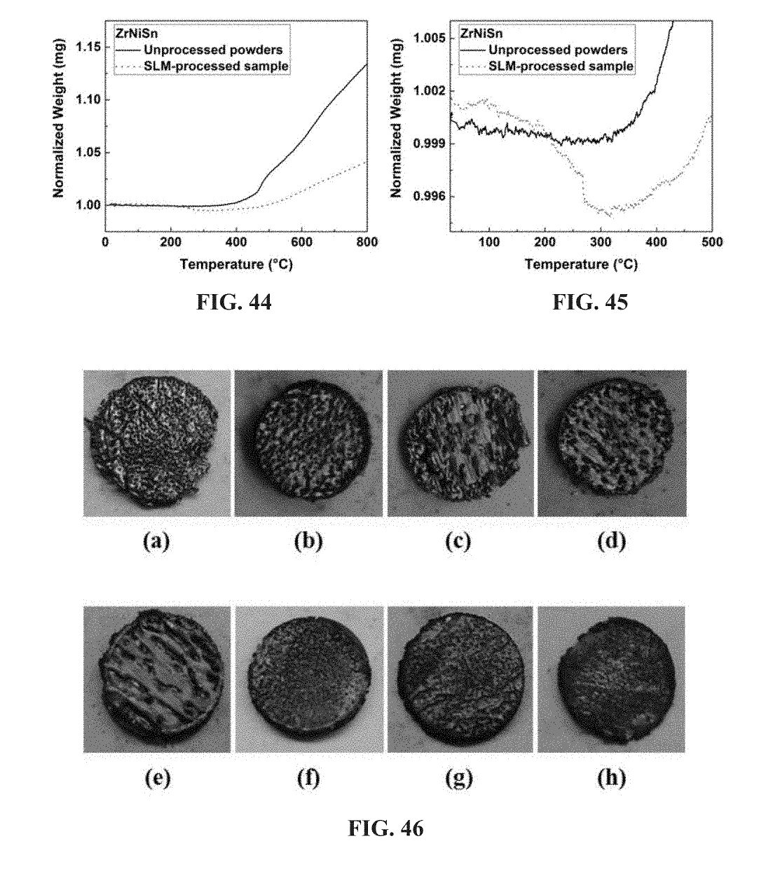

To further characterize the chemical properties with temperature, the SUM-produced part was first gently ground to powders then compared with original unprocessed powders through thermogravimetric analysis (TGA) using Perkin Elmer Pyris 1 TGA thermogravimetric analyzer. The TGA measurement was performed as follows. The whole system was first purged with nitrogen gas at 60 ml/min for 30 min to establish an oxygen deficient environment. After that, about 15 mg of powders were heated from 20 to 800° C. at a rate of 20° C./min, purged with nitrogen gas at the rate of 20 ml/min. The results (FIG. 44) show a generally similar trend that both the SLM-processed and the control powders gained weight at around 320° C. The increase of mass suggests oxidation, indicating the TGA experiment was not done in a strict oxygen free environment despite the nitrogen gas purging efforts. Nevertheless, the similarity for two curves suggests most of the processed powders preserved the material's composition. FIG. 45 is a magnified view for the two curves from 30 to 500° C. It shows the processed powders experienced a small mass decrease between 100-320° C. while the mass of the control powders was relatively stable in the same range. Hence, the TGA comparison suggests the processed sample has some impurity, indicating a small amount of decomposition during the laser processing. The TGA result was consistent with the powder XRD analysis.

Using SLM, solid freeform ingots for another half-Heusler material, Hf_{0.3}Zr_{0.7}CoSn_{0.3}Sb_{0.7}/nano-ZrO₂, were also successfully fabricated from loose powders. Due to differences in thermal conductivity, optical absorption, and powder flowability, SLM process parameters are generally material-dependent. The processing parameters required to form freeform ingots from Hf_{0.3}Zr_{0.7}CoSn_{0.3}Sb_{0.7}/nano-ZrO₂ were different from those for ZrNiSn. The optimal laser power, hatch distance, and scan speed were 20 W, 5-10 μm, and 350-500 mm/s, respectively. Under such conditions, disk-shaped ingots with diameters of about 8 mm and thicknesses over 1 mm were formed; they had flat but generally porous surfaces (FIGS. 46(a)-(h)). A typical SLM-produced sample (FIG. 46(a)) has a density of 4.22 g/cm³, about 45% of the original material with a density of 943 g/cm³.

FIG. 46 shows Hf_{0.3}Zr_{0.7}CoSn_{0.3}Sb_{0.7}/nano-ZrO₂ ingots produced in this experimental study. The corresponding laser processing parameters are shown in Table 7. Generally, all of the parts had rough surfaces. Those made with energy density in the middle of the range (FIGS. 46(f) and (g)) were better than those made with lower energy density (FIGS. 46(a)-(e)) or higher energy density (FIG. 46(h)), which is the same case we observed for ZrNiSn. Although the samples in FIGS. 46(e) and (f) were made with the same energy density, variable combinations of the processing parameters lead to different results with the part in FIG. 46(e) showing higher porosity and rougher surface. This suggests the effect of the three parameters is not the same on the product and the concept of laser energy density does not adequately capture the differences in each parameter. Since laser energy density does not completely reveal the complex physical processes during selective laser melting, it cannot be the only design parameter for the SLM process.

TABLE 7

| Hf_{0.3}Zr_{0.7}CoSn_{0.3}Sb_{0.7}/ | Power, | Scan Speed, | Hatch | Energy |
|---|---|---|---|---|
| nano-ZrO₂ | p | v | Distance, h | Density, E |
| Sample | (W) | (mm/s) | (μm) | (J/mm²) |
| (a) | 20 | 350 | 25 | 22.9 |
| (b) | 25 | 350 | 25 | 2.86 |
| (c) | 30 | 350 | 25 | 3.43 |
| (d) | 40 | 350 | 25 | 4.57 |
| (e) | 50 | 350 | 25 | 5.71 |
| (f) | 20 | 350 | 10 | 5.71 |
| (g) | 20 | 500 | 5 | 8.00 |
| (h) | 20 | 350 | 5 | 11.43 |

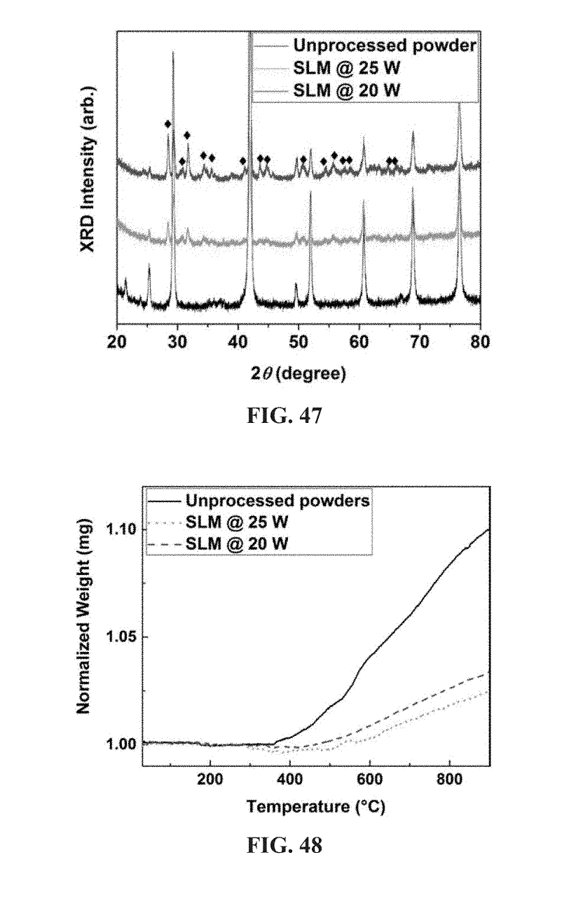

Powder XRD was performed for the Hf_{0.3}Zr_{0.7}CoSn_{0.3}Sb_{0.7}/nano-ZrO₂ samples for characterizing the chemical and structural changes. FIG. 47 shows the results for the unprocessed powders and ground powders from two laser processed samples with the process parameters of 20 W laser power and 10 μm hatch distance, and 25 W laser power and 25 μm hatch distance, respectively, with the same 350 mm/s scan speed. Compared to the control sample, the SLM-produced samples showed some decomposition, forming additional CoSn₃ and HfO₂. As the same case of ZrNiSn, the SLM process preserves most of the material structure of Hf_{0.3}Zr_{0.7}CoSn_{0.3}Sb_{0.7}/nano-ZrO₂ with some decomposition and oxidation.

FIG. 48 shows the TGA results for both unprocessed Hf_{0.3}Zr_{0.7}CoSn_{0.3}Sb_{0.7}/nano-ZrO₂ sample and the SLM produced samples with 20 W laser power and 10 μm hatch distance, and 25 W laser power and 25 μm hatch distance, respectively, with the same 350 mm/s scan speed. The procedure of TGA measurement was similar to that for ZrNiSn except the temperature range was 20-900° C. The result showed that the general trend is the same for the control material and the laser-processed materials, which suggest the majority of the original phase was preserved.

However, the weights for both SLM-produced samples started to slightly decrease between about 300-400° C. while the control sample showed constant weight until about 350° C.; then a continuous weight gain was observed. The difference beyond 300° C. suggests slight composition differences, consistent with the powder XRD indications. The increasing weight above 400° C. for all samples shows oxidation despite the nitrogen purging, similar to the ZiNiSn case.

Although the present invention and its objects, features and advantages have been described in detail, other embodiments are encompassed by the invention. All references cited. herein are incorporate by reference in their entireties. Finally, those skilled in the art should appreciate that they can readily use the disclosed conception and specific embodiments as a basis for designing or modifying other structures for carrying out the same purposes of the present invention without departing from the scope of the invention as defined by the appended claims.

What is claimed is:

1. A method of fabricating a shaped material, the method comprising:
irradiating a first layer of a powder with a laser to convert the powder to a first material layer;
disposing a second layer of the powder on the first material layer;
irradiating the second layer of the powder with the laser to convert the powder to a second material layer; and
fusing the first material layer and the second material layer to form a shaped material having semiconducting or thermoelectric properties.

2. The method of claim 1, wherein the laser is a continuous wave laser.

3. The method of claim 2, wherein the laser has an output power of up to 200 W.

4. The method of claim 2, wherein laser irradiation is conducted at a scan speed ranging from about 10 to about 5000 mm/s.

5. The method of claim 2, wherein laser irradiation is conducted at a hatch distance ranging from about 1 to about 1000 μm.

6. The method of claim 2, wherein laser irradiation is conducted with a laser beam focused to have a spot size between about 5 and about 1000 μm.

7. The method of claim 1, wherein the laser is a pulsed wave laser.

8. The method of claim 7, wherein the laser has an average output power of up to 40 W.

9. The method of claim 7, wherein laser irradiation is conducted at a scan speed ranging from about 5 to about 200 mm/s.

10. The method of claim 7, wherein laser irradiation is conducted with a laser beam focused to have a spot size between about 5 and about 500 μm.

11. The method of claim 1, wherein the powder is a bismuth chalcogenide, a lead chalcogenide, and tin chalcogenide, a half-Heusler compound, a full-Heusler compound, a metal silicide, a magnesium-group IV element compound, an inorganic clathrate, a silicon-germanium compound, a metal oxide, a skutterudite, a metal antimonide, a tetrahedrite, a copper ion material, a Zintl material, any doped equivalent thereof, or any mixture thereof.

12. The method of claim 1, wherein the first layer of the powder and the second layer of the powder are each disposed within a different thermally resistant ring prior to irradiation.

13. A shaped material formed according the process of claim 1, the shaped material having semiconducting or thermoelectric properties.

14. The shaped material of claim 13, wherein the material is made of a bismuth chalcogenide, a lead chalcogenide, and tin chalcogenide, a half-Heusler compound, a full-Heusler compound, a metal silicide, a magnesium-group IV element compound, an inorganic clathrate, a silicon-germanium compound, a metal oxide, a skutterudite, a metal antimonide, a tetrahedrite, a copper ion material, a Zintl material, or any combination thereof.

15. The shaped material of claim 13, wherein the shaped material is cubic, cuboidal, pyramidal, triangular prismatic, hexagonal prismatic, octagonal prismatic, cylindrical, spherical, hemispherical, conical, frustoconical, rhombic, a dumbbell, a torus, a star, a cross, a letter, a number, a symbol, a beam, a structured grid, an unstructured grid, a hybrid grid, or any combination thereof.

16. The shaped material of claim 13, wherein the shaped material is solid.

17. The shaped material of claim 13, wherein the shaped material is hollow along at least a portion of an axis of the shaped material.

18. A system for the fabrication of a shaped material, the system comprising:
an enclosure;
a powder containment vessel contained within the enclosure, the containment vessel comprising:
a base;
a powder storage section supported by the base; and
a shaped material formation section supported by the base and adjacent to the powder storage section;
a transfer mechanism for transferring a powder from the powder storage section to the shaped material formation section; and
a laser to irradiate the powder when the powder is located within the shaped material formation section.

19. The system of claim 18, further comprising a laser beam focusing assembly.

20. The system of claim 18, wherein the base is configured to move vertically within the containment vessel.
